(19) United States
(12) Patent Application Publication
(10) Pub. No.: US 2026/0312599 A1
(43) Pub. Date: Oct. 8, 2026

(54) NON-BINARY FULLY DIFFERENTIAL SAR ADC FOR AI-NAND

(71) Applicant: MICRON TECHNOLOGY, INC., BOISE, ID (US)

(72) Inventors: Huu Thai Hoa Nguyen, Hayward, CA (US); Kim-Fung Chan, Fremont, CA (US); Michele Piccardi, Cupertino, CA (US)

(73) Assignee: MICRON TECHNOLOGY, INC., BOISE, ID (US)

(21) Appl. No.: 19/637,149

(22) Filed: Apr. 2, 2026

Related U.S. Application Data
(60) Provisional application No. 63/784,351, filed on Apr. 7, 2025.

(51) Int. Cl. H03M 1/46; G06F 17/16; G11C 16/04; H03F 3/45

(52) U.S. Cl. CPC H03M 1/466; G06F 17/16; G11C 16/0483; H03F 3/45179; H03F 2203/45151; H03F 2203/45156

(57) ABSTRACT

A successive approximation register analog-to-digital converter (SAR ADC) might include a comparator having a first input and a second input, each selectively connected to a first voltage node configured to receive a common mode voltage level, a first array of capacitors each having a first electrode connected to the first input of the comparator, and a second array of capacitors each having a first electrode connected to the second input of the comparator. The second electrodes of each capacitor of the first array of capacitors might be selectively connected to receive one of a first input voltage level of the SAR ADC and one or more reference voltage levels. The second electrodes of each capacitor of the second array of capacitors might be selectively connected to receive one of a second input voltage level of the SAR ADC and the one or more reference voltage levels.

### RELATED APPLICATION

This application claims the benefit of U.S. Provisional Application No. 63/784,351, filed on Apr. 7, 2025, hereby incorporated herein in its entirety by reference.

### TECHNICAL FIELD

The present disclosure relates generally to integrated circuits and methods of their operation, and, in particular, in one or more embodiments, the present disclosure relates to memories configured to perform analog-to-digital conversion using a non-binary fully differential successive approximation register analog-to-digital converter (SAR ADC).

### BACKGROUND

Integrated circuit devices traverse a broad range of electronic devices. One particular type includes memory devices, often referred to simply as memory. Memory devices are typically provided as internal, semiconductor, integrated circuit devices in computers or other electronic devices. There are many different types of memory including random-access memory (RAM), read only memory (ROM), dynamic random access memory (DRAM), synchronous dynamic random access memory (SDRAM), and flash memory.

Flash memory has developed into a popular source of non-volatile memory for a wide range of electronic applications. Flash memory typically use a one-transistor memory cell that allows for high memory densities, high reliability, and low power consumption. Changes in threshold voltage (Vt) of the memory cells, through programming (which is often referred to as writing) of charge storage nodes (e.g., floating gates or charge traps) or other physical phenomena (e.g., phase change or polarization), determine the data state (e.g., data value) of each memory cell. Common uses for flash memory and other non-volatile memory include personal computers, personal digital assistants (PDAs), digital cameras, digital media players, digital recorders, games, appliances, vehicles, wireless devices, mobile telephones, and removable memory modules, and the uses for non-volatile memory continue to expand.

A NAND flash memory is a common type of flash memory device, so called for the logical form in which the basic memory cell configuration is arranged. Typically, the array of memory cells for NAND flash memory is arranged such that the control gate of each memory cell of a row of the array might be connected together to form an access line, such as a word line. Columns of the array include strings (often termed NAND strings) of memory cells connected together in series between a pair of select gates, e.g., a source select transistor and a drain select transistor. Each source select transistor might be connected to a common source, while each drain select transistor might be connected to a data line, such as column bit line. Variations using more than one select gate between a string of memory cells and the common source, and/or between the string of memory cells and the data line, are known.

An Artificial Neural Network (ANN) might use a network of neurons to process inputs to the network and to generate outputs from the network. In general, an ANN might be trained using supervised and/or unsupervised methods.

Deep learning might use multiple layers of machine learning to progressively extract features from input data, and might be implemented via ANNs, such as deep neural networks, deep belief networks, recurrent neural networks, and/or convolutional neural networks. Deep learning has been applied to many application fields, such as computer vision, speech/audio recognition, natural language processing, machine translation, bioinformatics, drug design, medical image processing, games, etc.

### BRIEF DESCRIPTION OF THE DRAWINGS

FIG. 1 is a simplified block diagram of a memory in communication with a processor as part of an electronic system, according to an embodiment.

FIGS. 2A-2C are schematics of a portion of an array of memory cells in accordance with an embodiment.

FIG. 3 details the computations of a Deep Learning Accelerator.

FIGS. 4A and 4B depict portions of an array of memory cells configured to store digits of a multiplicand in an analog fashion and a binary fashion, respectively, in accordance with embodiments.

FIG. 5 depicts a portion of an array of memory cells having a block of memory cells for use in discussing operations in accordance with embodiments.

FIG. 6A is an example of a Rectified Linear Unit (ReLU) activation function for use with embodiments.

FIG. 6B is an example of a Leaky ReLU activation function for use with embodiments.

FIG. 7 is a conceptual depiction of a Transimpedance Amplifier (TIA) selectively connected to an Analog-to-Digital Converter (ADC) in accordance with an embodiment.

FIG. 8 is a block schematic of a TIA as could be used with embodiments.

FIG. 9 is a conceptual depiction of an ADC as a non-binary fully differential successive approximation register analog-to-digital converter (SAR ADC) including a fully differential amplifier in accordance with an embodiment.

FIG. 10 is a block schematic of a fully-differential amplifier in accordance with an embodiment.

FIGS. 11A-11C are example graphs of possible inputs and outputs of a fully-differential amplifier and a corresponding relationship of the outputs in accordance with an embodiment.

FIG. 12 is a block schematic of a fully-differential amplifier in accordance with another embodiment.

FIG. 13 is an example decision tree of a non-binary SAR ADC as could be used with embodiments.

FIG. 14 is a block schematic of a non-binary SAR ADC in accordance with an embodiment.

FIG. 15A is a block schematic of a portion of a capacitor digital-to-analog converter (C-DAC) of the related art.

FIG. 15B is a block schematic of a portion of a C-DAC in accordance with an embodiment.

FIG. 16 is a schematic of an array of capacitors of a C-DAC of the SAR ADC of FIG. 14 for use in describing its operation.

FIG. 17 is a flowchart of a method of generating a representation of a differential input in accordance with an embodiment.

FIGS. 18A-18D are a flowchart of a method of generating a representation of a differential input in accordance with another embodiment.

### DETAILED DESCRIPTION

In the following detailed description, reference is made to the accompanying drawings that form a part hereof, and in which is shown, by way of illustration, specific embodiments. In the drawings, like reference numerals describe substantially similar components throughout the several views. Other embodiments might be utilized and structural, logical and electrical changes might be made without departing from the scope of the present disclosure. The following detailed description is, therefore, not to be taken in a limiting sense.

The term “conductive” as used herein, as well as its various related forms, e.g., conduct, conductively, conducting, conduction, conductivity, etc., refers to electrically conductive unless otherwise apparent from the context. Similarly, the term “connecting” as used herein, as well as its various related forms, e.g., connect, connected, connection, etc., refers to electrically connecting by a conductive path unless otherwise apparent from the context.

As used herein, multiple acts being performed concurrently will mean that each of these acts is performed for a respective time period, and each of these respective time periods overlaps, in part or in whole, with each of the remaining respective time periods. In other words, portions of each of those acts are simultaneously performed for at least some period of time.

Unless otherwise defined, directional references such as upper, top, lower, bottom, side, left, right, parallel, orthogonal, etc. as used in the description of the figures refers to such directions relative to the orientation of the figure itself.

It is recognized herein that even where values might be intended to be equal, variabilities and accuracies of industrial processing and operation might lead to differences from their intended values. These variabilities and accuracies will generally be dependent upon the technology utilized in fabrication and operation of the integrated circuit device. As such, if values are intended to be equal, those values are deemed to be equal regardless of their resulting values.

An Artificial Neural Network (ANN) might use a network of neurons to process inputs to the network and to generate outputs from the network. For example, each neuron in the network might receive a set of inputs. Some of the inputs to a neuron might be the outputs of certain neurons in the network, and some of the inputs to a neuron might be the inputs provided to the neural network. The input/output relations among the neurons in the network represent the neuron connectivity in the network.

Each neuron might have a bias, an activation function, and a set of synaptic weights for its inputs respectively. The activation function might be in the form of a step function, a linear function, a log-sigmoid function, a Rectified Linear Unit (ReLU) function, etc. Different neurons in the network might have different activation functions.

Each neuron might generate a weighted sum of its inputs and its bias and then produce an output that is the function of the weighted sum, computed using the activation function of the neuron.

The relations between the input(s) and the output(s) of an ANN in general might be defined by an ANN model that includes the data representing the connectivity of the neurons in the network, as well as the bias, activation function, and synaptic weights of each neuron. Based on a given ANN model, a computing device can be configured to compute the output(s) of the network from a given set of inputs to the network. For example, the inputs to an ANN might be generated based on camera inputs, and the outputs from the ANN might be the identification of an item, such as an event or an object.

In general, an ANN might be trained using a supervised method where the parameters in the ANN are adjusted to minimize or reduce the error between known outputs associated with or resulted from respective inputs and computed outputs generated via applying the inputs to the ANN. Examples of supervised learning/training methods include reinforcement learning and learning with error correction.

Alternatively, or in combination, an ANN might be trained using an unsupervised method where the exact outputs resulted from a given set of inputs is not known before the completion of the training. The ANN can be trained to classify an item into a plurality of categories, or data points into clusters. Multiple training algorithms can be employed for a sophisticated machine learning/training paradigm.

Deep learning might use multiple layers of machine learning to progressively extract features from input data. For example, lower layers can be configured to identify edges in an image, and higher layers can be configured to identify, based on the edges detected using the lower layers, items captured in the image, such as faces, objects, events, etc. Deep learning can be implemented via ANNs, such as deep neural networks, deep belief networks, recurrent neural networks, and/or convolutional neural networks.

Deep learning has been applied to many application fields, such as computer vision, speech/audio recognition, natural language processing, machine translation, bioinformatics, drug design, medical image processing, games, etc.

The granularity of a Deep Learning Accelerator (DLA) operating on vectors and matrices corresponds to the largest unit of vectors/matrices that can be operated upon during the execution of one instruction by the DLA. During the execution of the instruction for a predefined operation on vector/matrix operands, elements of vector/matrix operands can be operated upon by the DLA in parallel to reduce execution time and/or energy consumption associated with memory/data access. The operations on vector/matrix operands of the granularity of the DLA can be used as building blocks to implement computations on vectors/matrices of larger sizes.

The implementation of a typical/practical ANN involves vector/matrix operands having sizes that are larger than the operation granularity of the DLA. To implement such an ANN using the DLA, computations involving the vector/matrix operands of large sizes can be broken down to the computations of vector/matrix operands of the granularity of the DLA. The DLA can be programmed via instructions to carry out the computations involving large vector/matrix operands. For example, atomic computation capabilities of the DLA in manipulating vectors and matrices of the granularity of the DLA in response to instructions can be programmed to implement computations in an ANN.

In some implementations, the DLA might lack some of the logic operation capabilities of a typical Central Processing Unit (CPU). However, the DLA can be configured with sufficient logic units to process the input data provided to an ANN and generate the output of the ANN according to a set of instructions generated for the DLA. Thus, the DLA can perform the computation of an ANN with little or no help from a CPU or another processor. Optionally, a conventional general purpose processor can also be configured as part of the DLA to perform operations that cannot be implemented efficiently using the vector/matrix processing units of the DLA, and/or that cannot be performed by the vector/matrix processing units of the DLA.

A typical ANN can be described/specified in a standard format (e.g., Open Neural Network Exchange (ONNX)). A compiler can be used to convert the description of the ANN into a set of instructions for the DLA to perform calculations of the ANN. The compiler can optimize the set of instructions to improve the performance of the DLA in implementing the ANN.

The DLA can have local storage, such as registers, buffers and/or caches, configured to store vector/matrix operands and the results of vector/matrix operations. Intermediate results in the registers can be pipelined/shifted in the DLA as operands for subsequent vector/matrix operations to reduce time and energy consumption in accessing memory/data and thus speed up typical patterns of vector/matrix operations in implementing a typical ANN. The capacity of registers, buffers and/or caches in the DLA is typically insufficient to hold the entire data set for implementing the computation of a typical ANN. Thus, a random access memory coupled to the DLA might be configured to provide an improved data storage capability for implementing a typical ANN. For example, the DLA might load data and instructions from the random access memory and store results back into the random access memory.

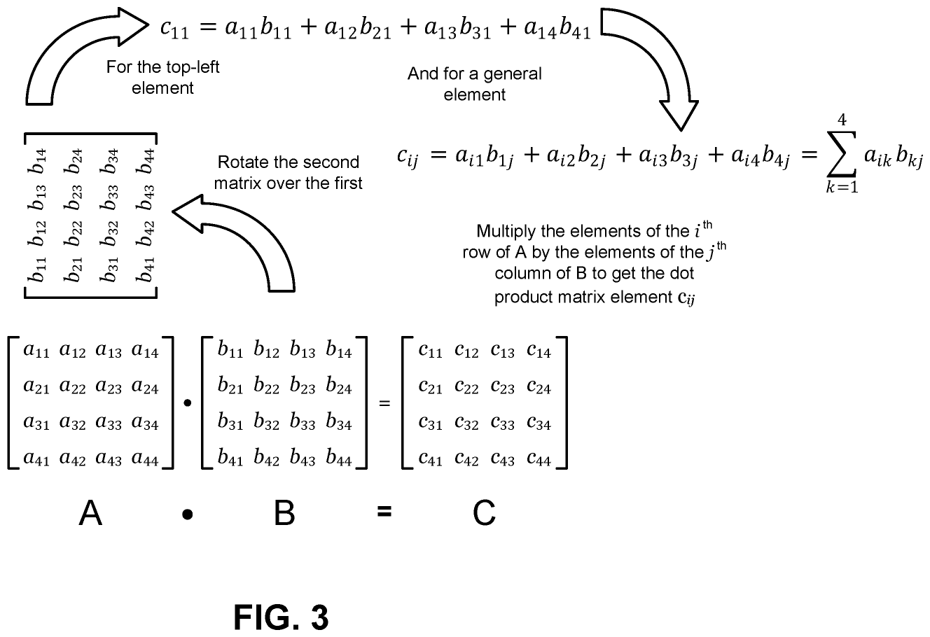

These computations can be replicated within a NAND memory as described in U.S. patent application Ser. No. 18/757,909 to Yudanov et al., filed Jun. 28, 2024, and titled VECTOR ELEMENT MULTIPLICATION IN NAND MEMORY. Specifically, an array of series-connected (e.g., NAND) memory cells can be configured to store data values representative of digits of elements of a multiplicand vector (e.g., a stored vector). A voltage level representative of a digit of an element of a multiplier vector (e.g., an input vector) might be applied to data lines connected to the memory cells storing the data values representative of the digits of element of the multiplicand vector and, with these memory cells connected to their respective data lines and a common source, a combined current through these strings of series-connected memory cells might be representative of a multiplication partial product of the element of the multiplicand vector and the digit of the element of the multiplier vector. By sequentially applying the remaining digits of the element of the multiplier vector in a similar manner, these multiplication partial products can be accumulated to generate the multiplication product of the element of the multiplicand vector and the element of the multiplier vector. These multiplication products can then be combined with other such multiplication products to generate a vector dot product of the multiplicand vector and the multiplier vector. And the vector dot products can be combined to generate a matrix dot product as will be described with reference to FIG. 3.

Application of the activation function to such multiplication results is typically performed in the digital domain, e.g., after the analog-to-digital conversion of the current representative of the multiplication partial product of an element of a multiplicand vector and a digit of an element of a multiplier vector. This typically involves the use of arithmetic-logic units at a cost of relatively advanced CMOS processing in fabrication, and relatively high power consumption during use.

Various embodiments described herein might make use of the application of an activation function in the analog domain, prior to the analog-to-digital conversion of the current representative of a multiplication partial product of an element of a multiplicand vector and a digit of an element of a multiplier vector. Such application of the activation function might facilitate lower fabrication cost of the relevant circuitry and lower power consumption during use, relative to the use of arithmetic-logic units.

Various embodiments might further facilitate improved accuracy of analog-to-digital conversion of a voltage level, e.g., an output voltage level from applying an activation function to a current flow representative of a value of a multiplication partial product, to a digital value, e.g., representative of the value of that multiplication partial product. Such improvement might be facilitated by differentially amplifying an output voltage level, and applying the differential voltage levels to inputs of a non-binary SAR ADC. Such improvement might further be facilitated by using bottom plate sampling of the differential voltage signals to mitigate gain error arising from parasitic capacitance of the SAR ADC.

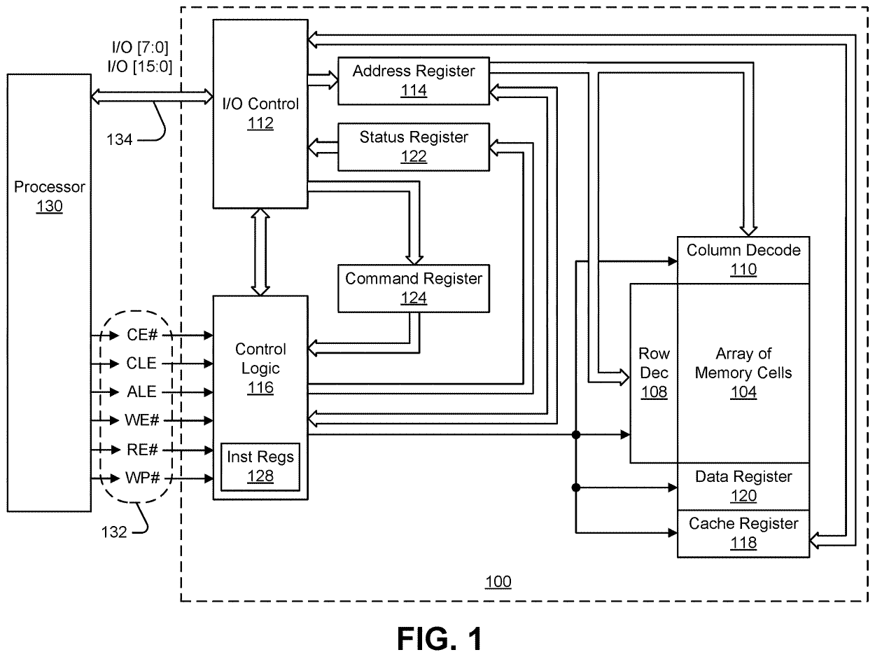

FIG. 1 is a simplified block diagram of a first apparatus, in the form of a memory (e.g., memory device) 100, in communication with a second apparatus, in the form of a processor 130, as part of a third apparatus, in the form of an electronic system, according to an embodiment. Some examples of electronic systems include personal computers, personal digital assistants (PDAs), digital cameras, digital media players, digital recorders, games, appliances, vehicles, wireless devices, mobile telephones and the like. The processor 130, e.g., a controller external to the memory device 100, might be a memory controller or other external host device.

Memory device 100 includes an array of memory cells 104 that might be logically arranged in rows and columns. Memory cells of a logical row are typically connected to the same access line (commonly referred to as a word line) while memory cells of a logical column are typically selectively connected to the same data line (commonly referred to as a bit line). A single access line might be associated with more than one logical row of memory cells and a single data line might be associated with more than one logical column. Memory cells (not shown in FIG. 1) of at least a portion of array of memory cells 104 are capable of being programmed to one of at least two different data states.

A row decode circuitry 108 and a column decode circuitry 110 are provided to decode address signals. Address signals are received and decoded to access the array of memory cells 104. Memory device 100 also includes input/output (I/O) control circuitry 112 to manage input of commands, addresses and data to the memory device 100 as well as output of data and status information from the memory device 100. An address register 114 is in communication with I/O control circuitry 112 and row decode circuitry 108 and column decode circuitry 110 to latch the address signals prior to decoding. A command register 124 is in communication with I/O control circuitry 112 and control logic 116 to latch incoming commands.

A controller (e.g., the control logic 116 internal to the memory device 100) controls access to the array of memory cells 104 in response to the commands from the external processor 130 and might generate status information for the external processor 130, i.e., control logic 116 is configured to perform array operations (e.g., sensing operations [which might include read operations and verify operations], programming operations and/or erase operations) on the array of memory cells 104 in accordance with embodiments. The control logic 116 is in communication with row decode circuitry 108 and column decode circuitry 110 to control the row decode circuitry 108 and column decode circuitry 110 in response to the addresses. The control logic 116 might include instruction registers 128 which might represent computer-usable memory for storing computer-readable instructions. For some embodiments, the instruction registers 128 might represent firmware. Alternatively, the instruction registers 128 might represent a grouping of memory cells, e.g., reserved block(s) of memory cells, of the array of memory cells 104.

Control logic 116 might also be in communication with a cache register 118. Cache register 118 latches data, either incoming or outgoing, as directed by control logic 116 to temporarily store data while the array of memory cells 104 is busy writing or reading, respectively, other data. During a programming operation (e.g., write operation), data might be passed from the cache register 118 to the data register 120 for transfer to the array of memory cells 104, then new data might be latched in the cache register 118 from the I/O control circuitry 112. During a read operation, data might be passed from the cache register 118 to the I/O control circuitry 112 for output to the external processor 130, then new data might be passed from the data register 120 to the cache register 118. The cache register 118 and/or the data register 120 might form (e.g., might form a portion of) a page buffer of the memory device 100. A data register 120 might further include sense circuits (not shown in FIG. 1) to sense a data state of a memory cell of the array of memory cells 104, e.g., by sensing a state of a data line connected to that memory cell. A status register 122 might be in communication with I/O control circuitry 112 and control logic 116 to latch the status information for output to the processor 130.

Memory device 100 receives control signals at control logic 116 from processor 130 over a control link 132. The control signals might include a chip enable CE #, a command latch enable CLE, an address latch enable ALE, a write enable WE #, a read enable RE #, and a write protect WP #. Additional or alternative control signals (not shown) might be further received over control link 132 depending upon the nature of the memory device 100. Memory device 100 receives command signals (which represent commands), address signals (which represent addresses), and data signals (which represent data) from processor 130 over a multiplexed input/output (I/O) bus 134 and outputs data to processor 130 over I/O bus 134.

For example, the commands might be received over input/output (I/O) pins [7:0] of I/O bus 134 at I/O control circuitry 112 and then might be written into command register 124. The addresses might be received over input/output (I/O) pins [7:0] of I/O bus 134 at I/O control circuitry 112 and then might be written into address register 114. The data might be received over input/output (I/O) pins [7:0] for an 8-bit device or input/output (I/O) pins [15:0] for a 16-bit device at I/O control circuitry 112 and then might be written into cache register 118. The data might be subsequently written into data register 120 for programming the array of memory cells 104. For another embodiment, cache register 118 might be omitted, and the data might be written directly into data register 120. Data might also be output over input/output (I/O) pins [7:0] for an 8-bit device or input/output (I/O) pins [15:0] for a 16-bit device. Although reference might be made to I/O pins, they might include any conductive nodes providing for electrical connection to the memory device 100 by an external device (e.g., processor 130), such as conductive pads or conductive bumps as are commonly used.

It will be appreciated by those skilled in the art that additional or alternative circuitry and signals can be provided, and that the memory device 100 of FIG. 1 has been simplified. It should be recognized that the functionality of the various block components described with reference to FIG. 1 might not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1.

Additionally, while specific I/O pins are described in accordance with popular conventions for receipt and output of the various signals, it is noted that other combinations or numbers of I/O pins (or other I/O node structures) might be used in the various embodiments.

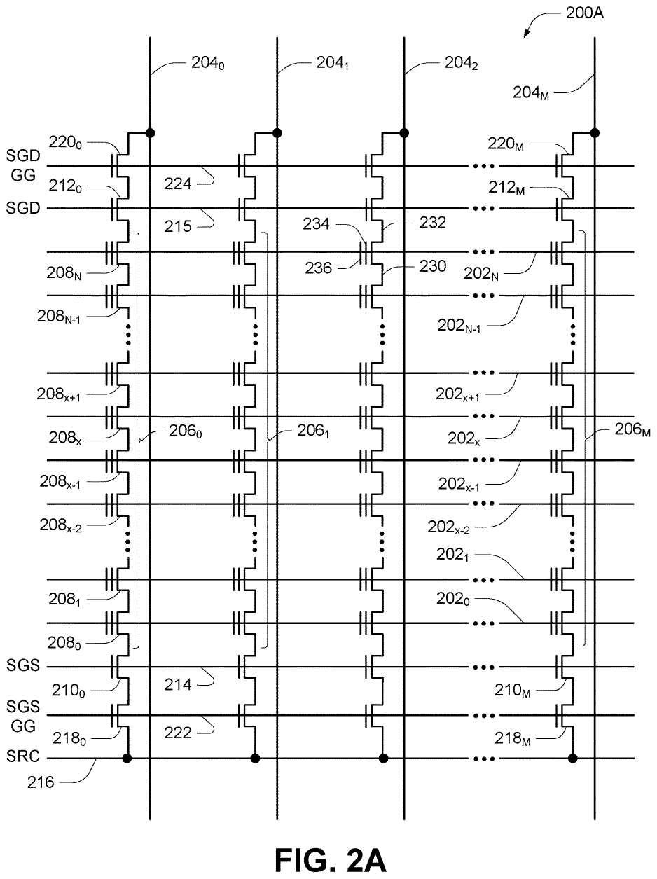

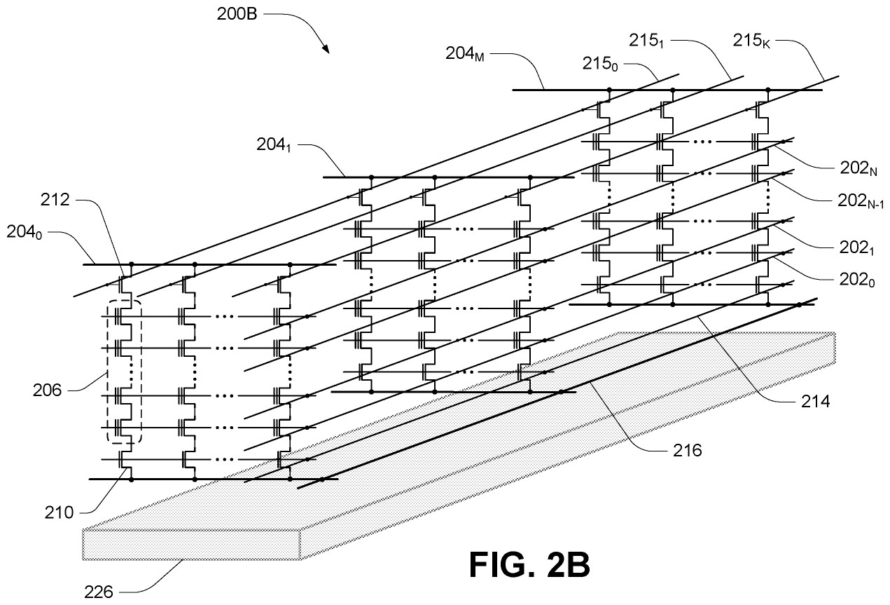

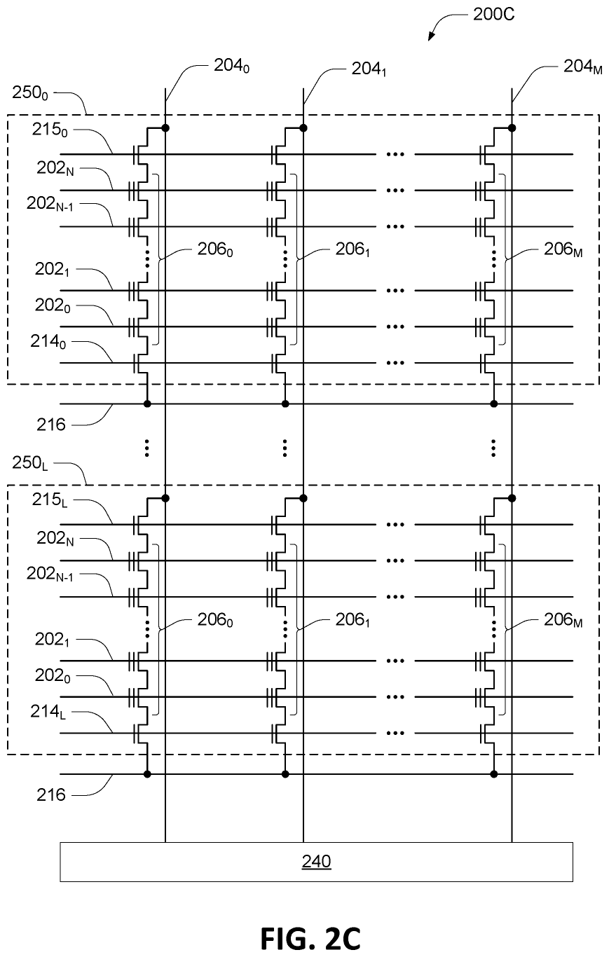

FIG. 2A is a schematic of a portion of an array of memory cells 200A, such as a NAND memory array, as could be used in a memory of the type described with reference to FIG. 1, e.g., as a portion of array of memory cells 104. Memory array 200A includes access lines, such as access lines (e.g., word lines) 202₀ to 202_{N}, and data lines, such as data lines (e.g., bit lines) 204₀ to 204_{M}. The access lines 202 might be connected to global access lines (e.g., global word lines), not shown in FIG. 2A, in a many-to-one relationship. For some embodiments, memory array 200A might be formed over a semiconductor that, for example, might be conductively doped to have a conductivity type, such as a p-type conductivity, e.g., to form a p-well, or an n-type conductivity, e.g., to form an n-well.

Memory array 200A might be arranged in rows (each corresponding to an access line 202) and columns (each corresponding to a data line 204). Each column might include a string of series-connected memory cells (e.g., non-volatile memory cells), such as one of NAND strings 206₀ to 206_{M}. Each NAND string 206 might be connected (e.g., selectively connected) to a common source (SRC) 216 and might include memory cells 208₀ to 208_{N}. The memory cells 208 might represent non-volatile memory cells for storage of data. Some of the memory cells 208 might represent dummy memory cells, e.g., memory cells not intended to store user data. Dummy memory cells are typically not accessible to a user of the memory, and are typically incorporated into the NAND string 206 for operational advantages, as are well understood.

The memory cells 208 of each NAND string 206 might be connected in series between a select gate 210 (e.g., a field-effect transistor), such as one of the select gates 210₀ to 210_{M} (e.g., that might be source select transistors, commonly referred to as select gate source), and a select gate 212 (e.g., a field-effect transistor), such as one of the select gates 212₀ to 212_{M} (e.g., that might be drain select transistors, commonly referred to as select gate drain). Select gates 210₀ to 210_{M} might be commonly connected to a select line 214, such as a source select line (SGS), and select gates 212₀ to 212_{M} might be commonly connected to a select line 215, such as a drain select line (SGD). Although depicted as traditional field-effect transistors, the select gates 210 and 212 might utilize a structure similar to (e.g., the same as) the memory cells 208. The select gates 210 and 212 might represent a plurality of select gates connected in series, with each select gate in series configured to receive a same or independent control signal. A control gate of each select gate 210 might be connected to select line 214. A control gate of each select gate 212 might be connected to select line 215.

The select gates 210 for each NAND string 206 might be connected in series between its memory cells 208 and a GIDL (gate-induced drain leakage) generator gate 218 (e.g., a field-effect transistor), such as one of the GIDL generator (GG) gates 218₀ to 218_{M}. The GG gates 218₀ to 218_{M} might be referred to as source GG gates. The source GG gates 218₀ to 218_{M} each might be connected (e.g., directly connected) to the common source 216, and selectively connected to their respective NAND strings 206₀ to 206_{M}. Alternatively, a source select gate 210 and its GG gate 218 might represent a single gate, e.g., connected (e.g., directly connected) to the common source 216, and connected (e.g., directly connected) to a respective NAND string 206.

The select gates 212 of each NAND string 206 might be connected in series between its memory cells 208 and a GG gate 220 (e.g., a field-effect transistor), such as one of the GG gates 220₀ to 220_{M}. The GG gates 220₀ to 220_{M} might be referred to as drain GG gates. The drain GG gates 220₀ to 220_{M} might be connected (e.g., directly connected) to their respective data lines 204₀ to 204_{M}, and selectively connected to their respective NAND strings 206₀ to 206_{M}. Alternatively, a drain select gate 212 and its GG gate 220 might represent a single gate, e.g., connected (e.g., directly connected) to a respective data line 204, and connected (e.g., directly connected) to a respective NAND string 206.

GG gates 218₀ to 218_{M} might be commonly connected to a control line 222, such as an SGS_GG control line, and GG gates 220₀ to 220_{M} might be commonly connected to a control line 224, such as an SGD_GG control line. Although depicted as traditional field-effect transistors, the GG gates 218 and 220 might utilize a structure similar to (e.g., the same as) the memory cells 208. The GG gates 218 and 220 might represent a plurality of GG gates connected in series, with each GG gate in series configured to receive a same or independent control signal. In general, the GG gates 218 and 220 might have threshold voltages different than (e.g., lower than) the threshold voltages of the select gates 210 and 212, respectively. Threshold voltages of the source GG gates 218 might be different than (e.g., higher than) threshold voltages of the drain GG gates 220. Threshold voltages of the GG gates 218 and 220 might be of an opposite polarity than, and/or might be lower than, threshold voltages of the select gates 210 and 212, respectively. For example, the select gates 210 and 212 might have positive threshold voltages (e.g., 2V to 4V), while the GG gates 218 and 220 might have negative threshold voltages (e.g., −1V to −4V). The GG gates 218 and 220 might be provided to assist in the generation of GIDL current into a channel of their corresponding NAND string 206 during an erase operation, for example.

A source of each GG gate 218 might be connected to common source 216. The drain of each GG gate 218 might be connected to a select gate 210 of the corresponding NAND string 206. For example, the drain of GG gate 218₀ might be connected to the source of select gate 210₀ of the corresponding NAND string 206₀. Therefore, in cooperation, each select gate 210 and GG gate 218 for a corresponding NAND string 206 might be configured to selectively connect that NAND string 206 to common source 216. A control gate of each GG gate 218 might be connected to control line 222.

The drain of each GG gate 220 might be connected to the data line 204 for the corresponding NAND string 206. For example, the drain of GG gate 220₀ might be connected to the data line 204₀ for the corresponding NAND string 206₀. The source of each GG gate 220 might be connected to a select gate 212 of the corresponding NAND string 206. For example, the source of GG gate 220₀ might be connected to select gate 212₀ of the corresponding NAND string 206₀. Therefore, in cooperation, each select gate 212 and GG gate 220 for a corresponding NAND string 206 might be configured to selectively connect that NAND string 206 to the corresponding data line 204. A control gate of each GG gate 220 might be connected to control line 224.

The memory array in FIG. 2A might be a quasi-two-dimensional memory array and might have a generally planar structure, e.g., where the common source 216, NAND strings 206 and data lines 204 extend in substantially parallel planes. Alternatively, the memory array in FIG. 2A might be a three-dimensional memory array, e.g., where NAND strings 206 might extend substantially perpendicular to a plane containing the common source 216 and to a plane containing the data lines 204 that might be substantially parallel to the plane containing the common source 216.

Typical construction of memory cells 208 includes a data-storage structure 234 (e.g., a floating gate, charge trap, or other structure configured to store charge) that can determine a data state of the memory cell (e.g., through changes in threshold voltage), and a control gate 236, as shown in FIG. 2A. The data-storage structure 234 might include both conductive and dielectric structures while the control gate 236 is generally formed of one or more conductive materials. In some cases, memory cells 208 might further have a defined source/drain (e.g., source) 230 and a defined source/drain (e.g., drain) 232. Memory cells 208 have their control gates 236 connected to (and in some cases form) an access line 202.

A column of the memory cells 208 might be a NAND string 206 or a plurality of NAND strings 206 selectively connected to a given data line 204. A row of the memory cells 208 might be memory cells 208 commonly connected to a given access line 202. A row of memory cells 208 can, but need not, include all memory cells 208 commonly connected to a given access line 202. Rows of memory cells 208 might often be divided into one or more groups of physical pages of memory cells 208, and physical pages of memory cells 208 often include every other memory cell 208 commonly connected to a given access line 202. For example, memory cells 208 commonly connected to access line 202_{N} and selectively connected to even data lines 204 (e.g., data lines 204₀, 204₂, 204₄, etc.) might be one physical page of memory cells 208 (e.g., even memory cells) while memory cells 208 commonly connected to access line 202_{N} and selectively connected to odd data lines 204 (e.g., data lines 204₁, 204₃, 204₅, etc.) might be another physical page of memory cells 208 (e.g., odd memory cells). Although data lines 204₃-204₅ are not explicitly depicted in FIG. 2A, it is apparent from the figure that the data lines 204 of the array of memory cells 200A might be numbered consecutively from data line 204₀ to data line 204_{M}. Other groupings of memory cells 208 commonly connected to a given access line 202 might also define a physical page of memory cells 208. For certain memory devices, all memory cells commonly connected to a given access line might be deemed a physical page of memory cells. The portion of a physical page of memory cells (which, in some embodiments, could still be the entire row) that is read during a single read operation or programmed during a single programming operation (e.g., an upper or lower page of memory cells) might be deemed a logical page of memory cells. A block of memory cells might include those memory cells that are configured to be erased together, such as all memory cells connected to access lines 202₀-202_{N} (e.g., all NAND strings 206 sharing common access lines 202). Unless expressly distinguished, a reference to a page of memory cells herein refers to the memory cells of a logical page of memory cells.

FIG. 2B is another schematic of a portion of an array of memory cells 200B as could be used in a memory of the type described with reference to FIG. 1, e.g., as a portion of array of memory cells 104. Like numbered elements in FIG. 2B correspond to the description as provided with respect to FIG. 2A. FIG. 2B provides additional detail of one example of a three-dimensional NAND memory array structure. For clarity, the GG gates and their control lines are not depicted in FIG. 2B.

The three-dimensional NAND memory array 200B might incorporate vertical structures which might include conductively-doped semiconductor pillars, which might be solid or hollow, around which memory cells of NAND strings 206 might be formed. A portion of a pillar might act as a body or channel (e.g., channel region) of the memory cells of NAND strings 206, e.g., a region through which current might flow when a memory cell, e.g., a field-effect transistor, is activated. Each of the NAND strings 206 might be selectively connected to a data line 204₀-204_{M} through a select gate 212 and to a common source 216 through a select gate 210. Multiple NAND strings 206 might be selectively connected to the same data line 204. Subsets of NAND strings 206 can be connected to their respective data lines 204 by biasing the select lines 215₀-215_{K} to selectively activate particular select gates 212 each between a NAND string 206 and a data line 204. The select gates 210 can be activated by biasing the select line 214. Each access line 202 might be connected to multiple rows of memory cells of the memory array 200B. Rows of memory cells that are commonly connected to each other by a particular access line 202 might collectively be referred to as tiers.

The three-dimensional NAND memory array 200B might be formed over peripheral circuitry 226. The peripheral circuitry 226 might represent a variety of circuitry for accessing the memory array 200B. The peripheral circuitry 226 might include complementary circuit elements. For example, the peripheral circuitry 226 might include both n-channel region and p-channel region transistors formed on a same semiconductor substrate, a process commonly referred to as CMOS, or complementary metal-oxide-semiconductors. Although CMOS often no longer utilizes a strict metal-oxide-semiconductor construction due to advancements in integrated circuit fabrication and design, the CMOS designation generally remains as a matter of convenience.

FIG. 2C is a further schematic of a portion of an array of memory cells 200C as could be used in a memory of the type described with reference to FIG. 1, e.g., as a portion of array of memory cells 104. Like numbered elements in FIG. 2C correspond to the description as provided with respect to FIG. 2A. Array of memory cells 200C might include strings of series-connected memory cells (e.g., NAND strings) 206, access (e.g., word) lines 202, data (e.g., bit) lines 204, select lines 214 (e.g., source select lines), select lines 215 (e.g., drain select lines) and common source 216 as depicted in FIG. 2A. A portion of the array of memory cells 200A might be a portion of the array of memory cells 200C, for example. FIG. 2C depicts groupings of NAND strings 206 into blocks of memory cells 250, e.g., blocks of memory cells 250₀-250_{L}. Blocks of memory cells 250 might be groupings of memory cells 208 that might be erased together in a single erase operation, sometimes referred to as erase blocks. Each block of memory cells 250 might represent those NAND strings 206 commonly associated with a single select line 215, e.g., select line 215₀. The common source 216 for the block of memory cells 250₀ might be a same source as the common source 216 for the block of memory cells 250_{L}. For example, each block of memory cells 250₀-250_{L} might be commonly selectively connected to the common source 216. Access lines 202 and select lines 214 and 215 of one block of memory cells 250 might have no direct connection to access lines 202 and select lines 214 and 215, respectively, of any other block of memory cells of the blocks of memory cells 250₀-250_{L}. Alternatively, the common source 216 for the block of memory cells 250₀ might be isolated from the common source 216 for the block of memory cells 250_{L}.

The data lines 204₀-204_{M} might be connected (e.g., selectively connected) to a buffer portion 240, which might be a portion of a data buffer of the memory. The buffer portion 240 might correspond to a memory plane (e.g., the set of blocks of memory cells 250₀-250_{L}). The buffer portion 240 might include sense circuits (not shown in FIG. 2C) for sensing data values indicated on respective data lines 204.

FIG. 3 details some computations supporting a deep learning accelerator (DLA).

Consider the example of the matrix A as a multiplicand and the matrix B as a multiplier. The dot product of these two matrices A and B to produce the results matrix C would include the dot product of the first row (e.g., vector) of the matrix A (e.g., a₁₁, a₁₂, a₁₃, and a₁₄) and the first column (e.g., vector) of the matrix B (e.g., b₁₁, b₂₁, b₃₁, and b₄₁) to yield the element of the matrix C of its first row and first column (e.g., c₁₁) according to Equation 1:

$${c}_{11} = {a}_{11} {b}_{11} + {a}_{12} {b}_{21} + {a}_{13} {b}_{31} + {a}_{14} {b}_{41} \qquad Eq . 1$$

Remaining elements of the matrix C might be similarly determined for the various rows of the matrix A and the various columns of the matrix B in a similar matter. For example, for each value of i from 1 to 4, and each value of j from 1 to 4 for the matrices depicted in FIG. 3, the element cᵢⱼ of the matrix C can be determined from the general Equation 2:

$${c}_{ij} = {a}_{i 1} {b}_{1 j} + {a}_{i 2} {b}_{2 j} + {a}_{i 3} {b}_{3 j} + {a}_{i 4} {b}_{4 j} = {\sum }_{k = 1}^{4} {a}_{ik} {b}_{kj} \qquad Eq . 2$$

Each element of the multiplicand matrix A, the multiplier matrix B, and the results matrix C might represent a number, which might be binary or otherwise. As such, each element of the results matrix C might represent a summation or accumulation of the products of corresponding elements of a row from the multiplicand matrix A and a column of the multiplier matrix B.

As noted earlier, these computations can be performed using a NAND memory. For example, to multiply two numbers within a NAND memory, a set of memory cells commonly connected to a same access line, or collectively connected to a set of access lines, could be programmed to have threshold voltages indicative of one number, e.g., the multiplicand, while voltages could be applied to the data lines selectively connected to the set of memory cells that are indicative of individual digits (e.g., bits) of the other number, e.g., the multiplier. Note that the multiplicand might utilize either binary encoding or thermometric encoding for storage of its data, e.g., the value of 12 base 10 might be binary encoded as 1100, or thermometric encoded as 111111111111. While thermometric encoding might utilize more memory cells for storage, it might also afford higher accuracy than binary encoding. Such encoding can be used to represent both positive and negative weights. For example, a value of −12 base 10 also might be binary encoded as 1100, or thermometric encoded as 111111111111, but this encoding might be stored to memory cells that can be read independently from memory cells storing encoded positive weights. In addition, the multiplication of positive weights of a multiplicand vector might be performed in a same manner as the multiplication of negative weights of the multiplicand vector. Their differentiation is not material to the present disclosure, but is described in U.S. Patent Application Ser. No. 63/709,627 to Piccardi, filed Oct. 21, 2024, and titled ANALOG PROCESSING OF SIGNED WEIGHTS IN ACTIVATION FUNCTIONS.

Subsets of the set of memory cells might be programmed to represent a respective digit (binary or thermometric) of the multiplicand, e.g., by collectively presenting a respective resistance value between their respective data lines and the common source in response to a same control signal or set of control signals applied to their control gates. Each subset of memory cells might contain one or more memory cells (which could include all memory cells) of a single string of series-connected memory cells, or of multiple strings of series-connected memory cells. As will be described in more detail, a subset of memory cells corresponding to one digit of the multiplicand might contain a same number of memory cells and/or a same arrangement of memory cells as the subsets of memory cells for each remaining digit of the multiplicand. Alternatively, a subset of memory cells corresponding to one digit of the multiplicand might contain a different number of memory cells and/or a different arrangement of memory cells than a respective subset of memory cells for one or more remaining digits of the multiplicand. The set of memory cells might be programmed in a binary fashion, e.g., each memory cell either activated (e.g., to represent a first logic level) or deactivated (e.g., to represent a second logic level different than the first logic level) in response to its respective control signal, or in an analog fashion, e.g., different memory cells exhibiting different levels of resistance (e.g., R, R/2, R/4, R/8, etc.) in response to a same control signal or same set of control signals.

Digits of the multiplicand having a negative weight might be stored to memory cells that are selectively connected to their respective data lines in response to different control signals than memory cells storing digits of the multiplicand having a positive weight. Alternatively, digits of the multiplicand having a negative weight might be stored to memory cells that are connected to different access lines than memory cells storing digits of the multiplicand having a positive weight. That is, digits of the multiplicand having a negative weight might be stored to memory cells that can be read independently from memory cells storing digits of the multiplicand having a positive weight. This permits the resulting current level of each multiplication partial product, e.g., which might both range from zero current level to some higher magnitude current level, to be processed independently as if it were a non-negative (e.g., zero to positive) current level for a first signed weight (e.g., a positive weight) or a non-positive (e.g., zero to negative) current level for a second signed weight (e.g., a negative weight).

Respective digits of the multiplier might be applied to the respective data lines of the set of memory cells sequentially while the set of memory cells for one signed weight receives its control signal or set of control signals. In this manner, the collective current level through the set of memory cells from its respective data lines to the common source might be indicative of the value of an element of the multiplicand vector multiplied by one digit of an element of the multiplier vector. The voltage levels corresponding to the digits of the multiplier vector might be applied in a binary fashion, e.g., applying a first voltage level to generate a first voltage differential between each data line and the common source (e.g., to represent a first logic level) and applying a second voltage level to generate a second voltage differential lower than the first voltage differential (e.g., a de minimis voltage differential) between each data line and the common source (e.g., to represent a second logic level different than the first logic level).

Alternatively, the voltage levels corresponding to the digits of the multiplier vector might be applied in an analog fashion. For example, to represent the first logic level (e.g., 1) for a least significant digit (e.g., least significant bit or LSB), a first voltage level might be applied to its respective data line(s) to generate a first voltage differential between the respective data line(s) and the common source, to represent the first logic level for a next significant digit (e.g., a second digit), a second voltage level higher than the first voltage level (e.g., two times the first voltage level) might be applied to its respective data line(s) to generate a second voltage differential (e.g., two times the first voltage differential) between the respective data line(s) and the common source, to represent the first logic level for a next significant digit (e.g., a third digit), a third voltage level higher than the second voltage level (e.g., two times the second voltage level) might be applied to its respective data line(s) to generate a third voltage differential (e.g., two times the second voltage differential) between the respective data line(s) and the common source, and so on. Similarly, to represent the second logic level (e.g., 0) for any digit, a voltage level might be applied to the data lines to generate a voltage differential lower than any voltage differential generated for the first logic level (e.g., a de minimis voltage differential) between each data line and the common source.

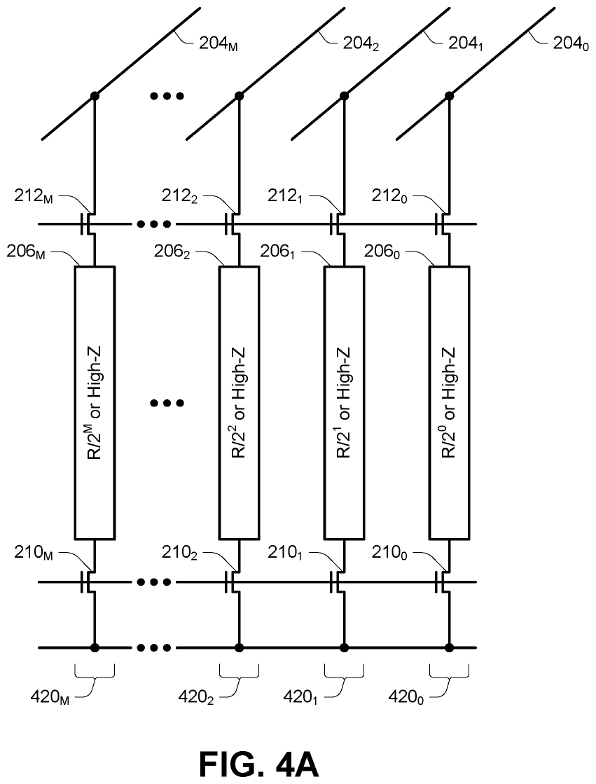

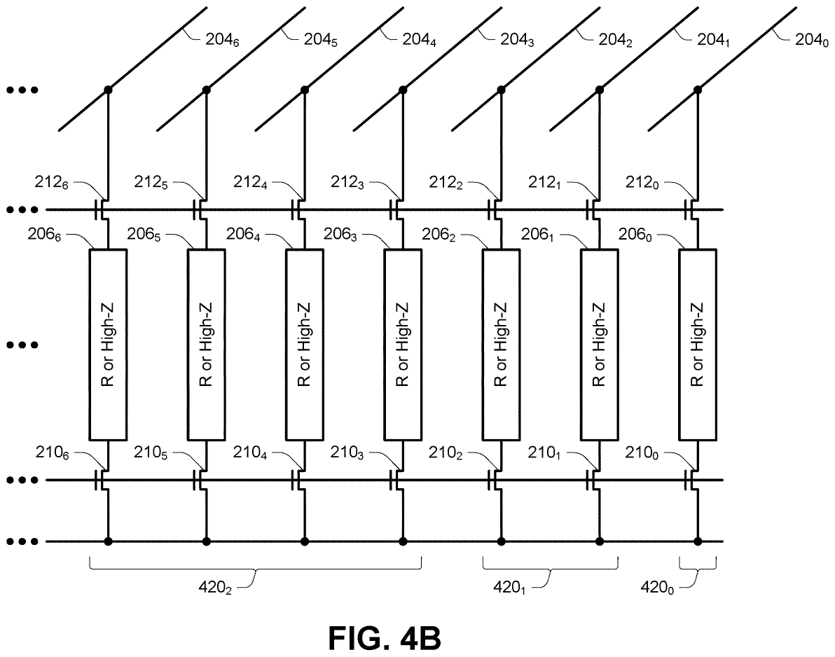

FIGS. 4A and 4B depict portions of an array of memory cells configured to store digits of a multiplicand in an analog fashion and a binary fashion, respectively. Like numbered elements in FIGS. 4A-4B correspond to the description as provided with respect to FIG. 2A. Note that the access lines 202 are not depicted in FIGS. 4A-4B for clarity. Note that the digit representations described in FIGS. 4A-4B might be for digits of a first signed weight or a second signed weight. Signed weights might be processed differently, but they might be stored in a similar (e.g., same) manner.

In FIG. 4A, the subset of memory cells corresponding to a first digit 420₀ of the multiplicand, e.g., a least significant digit, might include one or more (e.g., which might include all memory cells) memory cells of the string of series-connected memory cells 206₀ that are configured either to exhibit a resistance value of R/2⁰ or R to represent a first logic level (e.g., 1) for the digit 420₀, or to exhibit a high impedance (High-Z) to represent a second logic level (e.g., 0) different than the first logic level for the digit 420₀ in response to a set of control signals applied to the access lines 202 (not depicted in FIG. 4A) for the strings of series-connected memory cells 206. The subset of memory cells corresponding to a next digit 420₁ of the multiplicand might include one or more memory cells (e.g., which might include all memory cells) of the string of series-connected memory cells 206₁ that are configured either to exhibit a resistance value of R/2¹ or R/2 to represent the first logic level for the digit 420₁, or to exhibit a high impedance to represent the second logic level for the digit 420₁ in response to the set of control signals applied to the access lines 202 (not depicted in FIG. 4A) for the strings of series-connected memory cells 206. The subset of memory cells corresponding to a next digit 420₂ of the multiplicand might include one or more memory cells (e.g., which might include all memory cells) of the string of series-connected memory cells 206₂ that are configured either to exhibit a resistance value of R/2² or R/4 to represent the first logic level for the digit 420₂, or to exhibit a high impedance to represent the second logic level for the digit 420₂ in response to the set of control signals applied to the access lines 202 (not depicted in FIG. 4A) for the strings of series-connected memory cells 206. This might continue in like fashion for each additional digit 420 of the multiplicand up to a last digit 420_{M} of the multiplicand, e.g., a most significant digit, such that the subset of memory cells corresponding to the last digit 420_{M} of the multiplicand might include one or more memory cells (e.g., which might include all memory cells) of the string of series-connected memory cells 206_{M} that are configured either to exhibit a resistance value of R/2^{M} to represent the first logic level for the digit 420_{M}, or to exhibit a high impedance to represent the second logic level for the digit 420_{M} in response to the set of control signals applied to the access lines 202 (not depicted in FIG. 4A) for the strings of series-connected memory cells 206. In this manner, each string of series-connected memory cells 206 might correspond to a respective digit (e.g., a single respective digit) of the multiplicand, and each digit of the multiplicand might correspond to one or more strings of series-connected memory cells 206.

Note that although FIG. 4A depicts a single string of series-connected memory cells 206 as corresponding to each digit 420 of the multiplicand, each digit 420 of the multiplicand might correspond to one or more strings of series-connected memory cells 206. For example, the subset of memory cells corresponding to the first digit 420₀ of the multiplicand might include one or more memory cells of two strings of series-connected memory cells 206 that are each configured either to exhibit a resistance value of R to represent the first logic level for the digit 420₀ or to exhibit a high impedance to represent the second logic level for the digit 420₀, the subset of memory cells corresponding to the second digit 420₁ of the multiplicand might include one or more memory cells of two strings of series-connected memory cells 206 that are each configured either to exhibit a resistance value of R/2 to represent the first logic level for the digit 420₁ or to exhibit a high impedance to represent the second logic level for the digit 420₁, the subset of memory cells corresponding to the third digit 420₂ of the multiplicand might include one or more memory cells of two strings of series-connected memory cells 206 that are each configured either to exhibit a resistance value of R/4 to represent the first logic level for the digit 420₂ or to exhibit a high impedance to represent the second logic level for the digit 420₂, and so on. In addition, although the strings of series-connected memory cells 206 corresponding to each digit 420 of the multiplicand are depicted to be immediately adjacent one another, the strings of series-connected memory cells 206 corresponding to the digits 420 of the multiplicand might be interleaved with strings of series-connected memory cells 206 not corresponding to the digits 420 of the multiplicand, e.g., every other string of series-connected memory cells 206 or some other mixture of strings of series-connected memory cells 206 corresponding to the digits 420 of the multiplicand and strings of series-connected memory cells 206 not corresponding to the digits 420 of the multiplicand. Furthermore, while depicted to be arranged in an order from least significant digit 420₀ to most significant digit 420_{M}, their order could be altered or even randomized as this would not be expected to alter their collective conductance in any significant manner.

In FIG. 4B, the subset of memory cells corresponding to a first digit 420₀ of the multiplicand, e.g., a least significant digit, might include one or more memory cells (e.g., which might include all memory cells) of the string of series-connected memory cells 206₀ that are configured either to exhibit a resistance value of R to represent a first logic level (e.g., 1) for the digit 420₀, or to exhibit a high impedance to represent a second logic level (e.g., 0) different than the first logic level for the digit 420₀ in response to a set of control signals applied to the access lines 202 (not depicted in FIG. 4B) for the strings of series-connected memory cells 206. The subset of memory cells corresponding to a next digit 420₁ of the multiplicand might include one or more memory cells (e.g., which might include all memory cells) of the strings of series-connected memory cells 206₁ and 206₂ that are configured either to exhibit a resistance value of R for each string of series-connected memory cells 206 to represent the first logic level for the digit 420₁, or to exhibit a high impedance for each string of series-connected memory cells 206 to represent the second logic level for the digit 420₁ in response to the set of control signals applied to the access lines 202 (not depicted in FIG. 4B) for the strings of series-connected memory cells 206. The subset of memory cells corresponding to a next digit 420₂ of the multiplicand might include one or more memory cells (e.g., which might include all memory cells) of the strings of series-connected memory cells 206₃ through 206₆ that are configured either to exhibit a resistance value of R for each string of series-connected memory cells 206 to represent the first logic level for the digit 420₂, or to exhibit a high impedance for each string of series-connected memory cells 206 to represent the second logic level for the digit 420₂ in response to the set of control signals applied to the access lines 202 (not depicted in FIG. 4B) for the strings of series-connected memory cells 206. This might continue in like fashion for each additional digit 420 of the multiplicand up to a last digit of the multiplicand, e.g., a most significant digit, such that the subset of memory cells corresponding to each digit of the multiplicand might include one or more memory cells (e.g., which might include all memory cells) of a number of strings of series-connected memory cells 206 that might be two times the number of strings of series-connected memory cells 206 corresponding to a previous digit of the multiplicand, where each string of series-connected memory cells 206 corresponding to that digit of the multiplicand is configured either to exhibit a resistance value of R to represent the first logic level for that digit 420, or to exhibit a high impedance to represent the second logic level for that digit 420 in response to the set of control signals applied to the access lines 202 (not depicted in FIG. 4B) for the strings of series-connected memory cells 206.

As with the example of FIG. 4A, the first digit of the multiplicand 420₀ might correspond to more than one string of series-connected memory cells 206, with like adjustments to the number of strings of series-connected memory cells 206 for each remaining digit of the multiplicand. In addition, strings of series-connected memory cells 206 corresponding to the digits 420 of the multiplicand might be interleaved with strings of series-connected memory cells 206 not corresponding to the digits 420 of the multiplicand, and/or might be rearranged. Furthermore, FIG. 4B also might be used to describe thermometric encoding. For example, a set of memory cells being programmed to represent a number in thermometric encoding might include one or more memory cells (e.g., which might include all memory cells) of a number of strings of series-connected memory cells 206 that is a multiple (e.g., 1, 2, 3, etc.) of the number to be represented, e.g., to represent 3 base 10, the set of memory cells might include one or more memory cells of each of three strings of series-connected memory cells 206, e.g., strings of series-connected memory cells 206₀-206₂, each configured to exhibit a resistance value of R, with remaining strings of series-connected memory cells 206 corresponding to the multiplicand might be configured to exhibit a high impedance.

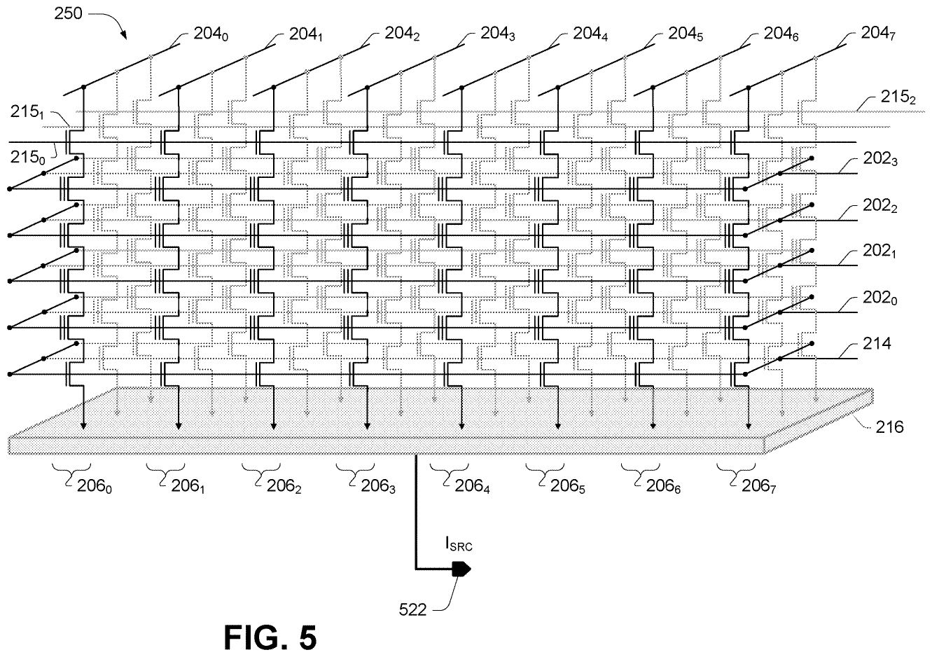

FIG. 5 depicts a portion of an array of memory cells (e.g., a block of memory cells 250) for use in discussing arithmetic operations in accordance with embodiments. FIG. 5 depicts eight strings of series-connected memory cells (e.g., 206₀-206₇) including memory cells (not labeled in FIG. 5) selectively connected to data lines 204₀-204₇ through select gates (not labeled in FIG. 5) responsive to a control signal applied to select line 215₀ and selectively connected to a common source 216 through select gates (not labeled in FIG. 5) responsive to a control signal applied to select line 214, eight strings of series-connected memory cells (not labeled in FIG. 5) including memory cells (not labeled in FIG. 5) selectively connected to data lines 204₀-204₇ through select gates (not labeled in FIG. 5) responsive to a control signal applied to select line 215₁ and selectively connected to the common source 216 through select gates (not labeled in FIG. 5) responsive to a control signal applied to select line 214, and eight strings of series-connected memory cells (not labeled in FIG. 5) including memory cells (not labeled in FIG. 5) selectively connected to data lines 204₀-204₇ through select gates (not labeled in FIG. 5) responsive to a control signal applied to select line 215₂ and selectively connected to the common source 216 through select gates (not labeled in FIG. 5) responsive to a control signal applied to select line 214.

During a sensing operation, a sense voltage level might be applied to a selected access line, e.g., access line 202₃ of FIG. 5. The sense voltage level might be configured to activate memory cells connected to the selected access line storing a first data value and to deactivate memory cells connected to the selected access line storing a second data value. These memory cells might store weights of the multiplication partial product, which might be of a first signed weight or a second signed weight. Note that for embodiments storing one or more than two data states to each memory cell, the sense voltage might be configured to further activate memory cells storing any one of the additional data values, e.g., other than the first data value or the second data value, albeit to differing degrees. Remaining unselected access lines, e.g., access lines 202₀-202₂, might receive a pass voltage level configured to activate memory cells connected to the unselected access lines regardless of their stored data values. All other transistors between the selected memory cells and the data lines 204 and between the selected memory cells and the common source 216 might also be activated. For example, in the example of FIG. 5, the select line 214 might receive a voltage level configured to activate the source select transistors, and one or more of the select lines 215₀-215₂ might receive a voltage level configured to activate the corresponding drain select transistors. Note that while in a traditional sensing operation, only one of the select lines 215₀-215₂ might receive a voltage level configured to activate its corresponding drain select transistors, because the sensing is occurring from the source side, more than one selected memory cell can be concurrently connected to its corresponding data line. Thus, various embodiments might connect one or more NAND strings 206 to an individual data line 204 during a sensing operation. This facilitates an increase in the number of memory cells available to represent an element of a multiplicand vector in a single sensing operation, e.g., increasing the number of available digits to represent the element. Similarly, only one of the access lines 202 might receive the sense voltage in a traditional sensing operation, but various embodiments might apply the sense voltage to more than one access line 202 during the sensing operation.

With the selected memory cells connected to their respective data lines 204 and to the common source 216, one or more of the data lines 204, e.g., one or more of the data lines 204₀-204₇, might receive a voltage level representative of a digit of an element of a multiplier vector. For example, in response to the value of the digit of the multiplier vector having a first input data value, the data lines 204 might receive a positive voltage level, and in response to the value of the digit of the multiplier vector having a second input data value, the data lines 204 might receive a reference potential, e.g., 0V, Vss, or ground, or a same voltage level as the common source 216. The resulting combined current flow through the selected memory cells to the common source 216 might represent a multiplication partial product of the weights of one sign and the digit of the multiplier vector. The node 522 might sink this current flow (e.g., I_{SRC}) from the common source 216 during the sensing operation. This process could be repeated for weights of the other sign.

For example, weights having a first sign might be stored to memory cells connected to a first subset of the access lines 202 of the block of memory cells 250, e.g., to the access lines 202₀-202₁, and weights having a second sign different than the first sign might be stored to memory cells selectively connected to a second, mutually exclusive, subset of the access lines 202 of the block of memory cells 250, e.g., to the access lines 202₂-202₃.

Alternatively, weights having a first sign might be stored to memory cells selectively connected to the data lines 204 of the block of memory cells 250 in response to a control signal on a first subset of select lines 215, e.g., in response to a control signal on the select line 215₀, and weights having a second sign different than the first sign might be stored to memory cells selectively connected to the data lines 204 in response to a control signal from a second, mutually exclusive, subset of the select lines 215 of the block of memory cells 250, e.g., in response to a control signal on the select line 215₁. This can include memory cells connected to one or more of the access lines 202.

Still further embodiments might store weights having a first sign to memory cells selectively connected to a first subset of the data lines 204 of the block of memory cells 250, e.g., to the data lines 204₀-204₃, and might store weights having a second sign different than the first sign to memory cells selectively connected to a second, mutually exclusive, subset of the data lines 204 of the block of memory cells 250, e.g., to the data lines 204₄-204₇. This also can include memory cells connected to one or more of the access lines 202. For such embodiments, during a sensing operation of memory cells storing weights having the first sign, data lines connected to memory cells storing weights of the second sign might receive a voltage level configured to not cause current flow through those memory cells, e.g., those data lines might receive the reference potential or a same voltage level as the common source 216. Similarly, during a sensing operation of memory cells storing weights having the second sign, data lines connected to memory cells storing weights of the first sign might receive a voltage level configured to not cause current flow through those memory cells, e.g., those data lines might receive the reference potential or a same voltage level as the common source 216.

Activation functions are utilized in determining the output of a neuron of an artificial neural network. One common activation function is the ReLU or Rectified Linear Unit activation function. An example of a ReLU activation function is provided by Equation 3:

$$f ( x ) = a * max ( 0 , x ) = a * ( x + \vert x \vert ) / 2 \qquad Eq . 3$$

ReLU activation functions have gained significant popularity for DLAs because they have been shown to facilitate supervised deep neural networks without requiring unsupervised pre-training, and are generally thought to provide faster training with large or complex data sets than sigmoid or other similar activation functions.

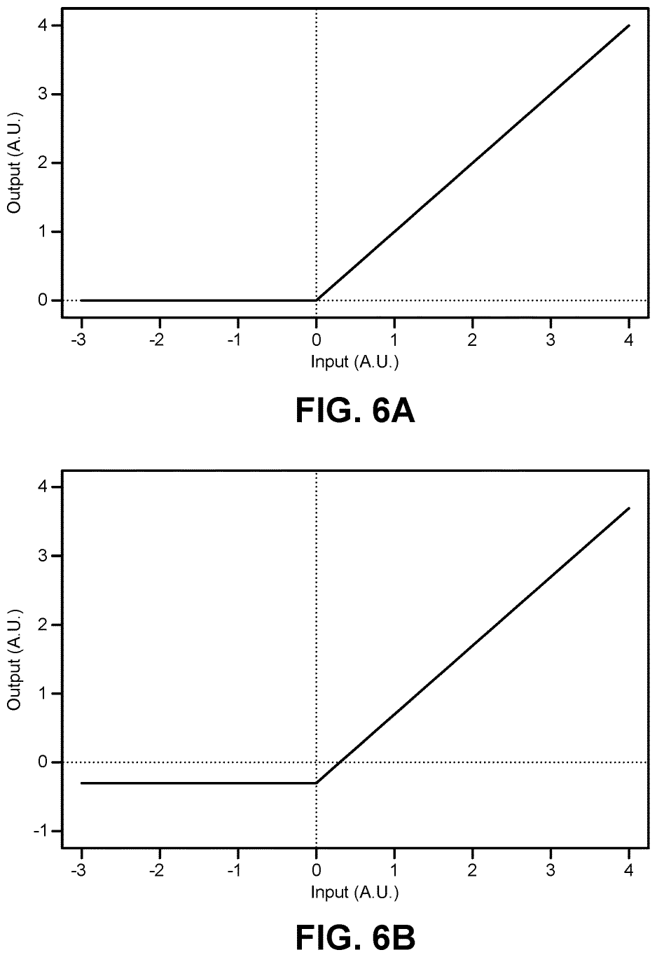

ReLU activation functions generally return a zero output for all non-positive inputs, and an increasing output for increasing values of positive inputs. A Leaky ReLU activation function is similar to ReLU but is capable of returning a negative output value, e.g., in response to negative inputs. Leaky ReLU might facilitate mitigation of vanishing gradients with ReLU and permit the definition of more generalized models. FIG. 6A is an example of a ReLU activation function, while FIG. 6B is an example of a Leaky ReLU activation function, which might alternatively be referred to as a Shifted ReLU activation function. In the examples of FIGS. 6A and 6B, the inputs and outputs each might be expressed in terms of arbitrary units (A.U.) of voltage, current, or some other metric.

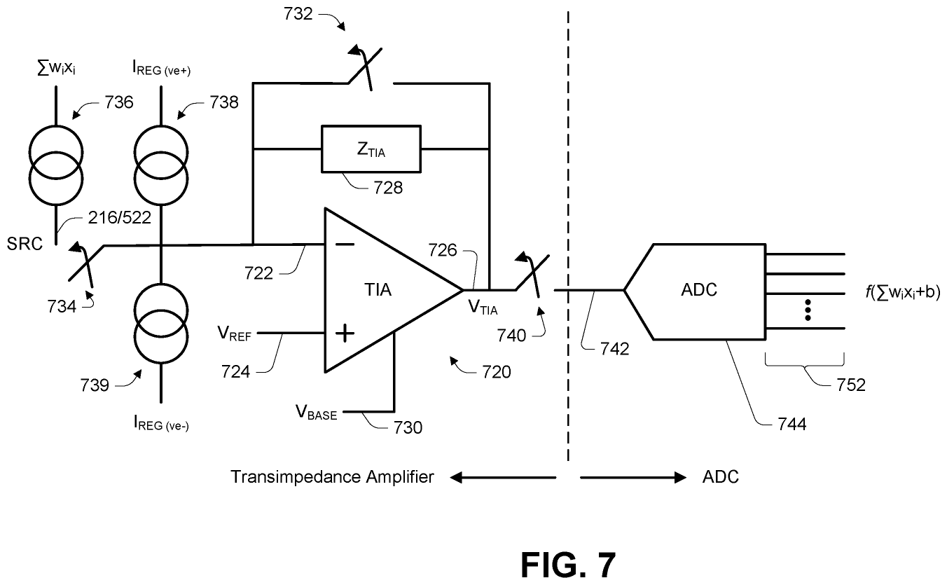

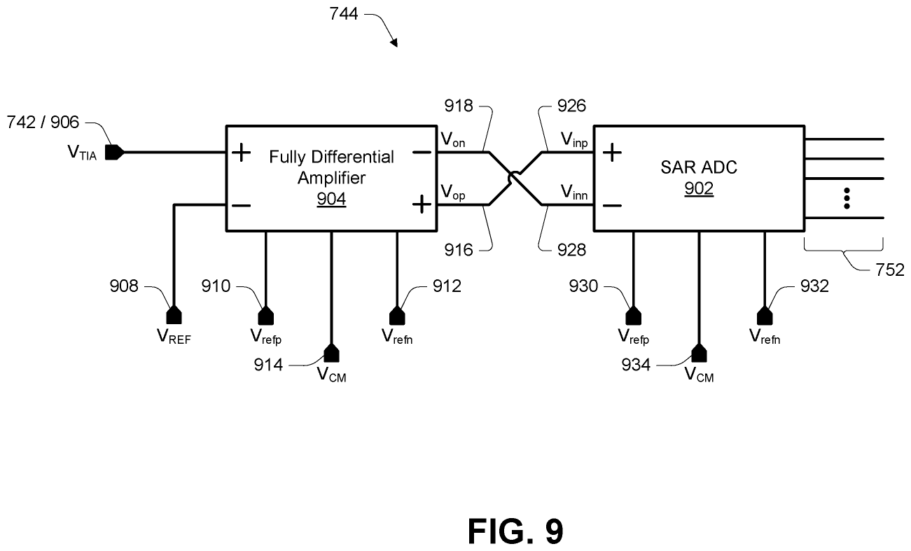

ReLU and/or Leaky ReLU activation functions as described herein might be implemented using a transimpedance amplifier (TIA) to convert the current levels representative of a multiplication partial product for weights of both signs, e.g., from the common source 216 during two sensing operations for both signed weights, to a voltage level representative of the multiplication partial product with the applied activation function. FIG. 7 is a conceptual depiction of a TIA selectively connected to an analog-to-digital converter (ADC) in accordance with an embodiment. As will be described with reference to FIG. 9, the ADC 744 might represent a non-binary fully differential successive approximation register analog-to-digital converter (SAR ADC) including a fully differential amplifier (FDA) in accordance with an embodiment.

In FIG. 7, the TIA 720 might have a first input 722, a second input 724, an output 726, and an impedance (Z_{TIA}) 728 connected between its first input 722 and its output 726. The first input 722 might be an inverted input, and the second input 724 might be a non-inverted input. The second input 724 might be configured to receive a voltage level V_{REF}, e.g., a reference voltage level. The TIA 720 might further include a voltage node 730 configured to receive a voltage level VBASE, a base voltage level. This might represent the lowest voltage level received by the TIA 720, e.g., providing a lowest value of its output voltage level.

The impedance 728 might represent a resistor, and might generally include one or more active or passive circuit elements configured to present a level of resistance (e.g., a predetermined level of resistance) to current flow from the first input 722 to the output 726, e.g., in excess of the conductive lines between the first input 722 and the output 726. In general, a TIA is configured as an operational amplifier (e.g., op-amp) with an impedance connected between its first input and its output. Although not depicted, a capacitance (e.g., a capacitor) might further be connected between the first input 722 and the output 726 in parallel with the impedance 728.

Unconventionally, for various embodiments, the TIA 720 might further include a switch 732 connected between the first input 722 and the output 726 in parallel with the impedance 728, e.g., to permit a direct connection between the first input 722 and the output 726, bypassing the impedance 728. The switch 732 might represent a field-effect transistor (FET), which might be an n-type FET (e.g., nFET) or a p-type FET (e.g., pFET).

The first input 722 of the TIA 720 might be selectively connected to the node 522 and thus to the common source 216 through a switch 734 in order to receive a current from the node 522 representative of a multiplication partial product. This might be represented by Σwᵢxᵢ, where wᵢ might represent a weight, e.g., a value stored to one of the selected memory cells and having either a first sign or a second sign, and xᵢ might represent an input, e.g., a value applied to the corresponding data line for that selected memory cell. The switch 734 might represent a FET, which might be an nFET or a pFET. The current source 736 might represent the memory cells generating the current, such as discussed with reference to FIG. 5.

The current source 738 might represent circuitry for sampling a level of current from the TIA 720 for one portion of its operation, and for supplying the sampled current level to the TIA 720 for another portion of its operation. Although depicted as a single current source, the current source 738 might represent first circuitry for sampling the level of current level from the TIA 720 and second circuitry for supplying the sampled current level to the TIA 720 that are different from one another. The current source 739 might represent circuitry for sampling a level of current from the TIA 720 for one portion of its operation, and for sinking the sampled current level from the TIA 720 for another portion of its operation. Although depicted as a single current source, the current source 739 might represent first circuitry for sampling the level of current level from the TIA 720 and second circuitry for supplying the sampled current level to the TIA 720 that are different from one another.

As used herein, sampling a current level might involve generating another current level proportional to (e.g., equal to) an original current level. The other current level proportional to the original current level might be referred to as a sampled current level. This might further involve sampling a control gate voltage level configured to pass a current level equal to the original current level through a first transistor, retaining that control gate voltage level, and using the retained control gate voltage level to generate the other current level proportional to (e.g., equal to) the original current level through a different transistor of a same type (e.g., n-type or p-type). Alternatively, this might further involve applying a first control gate voltage level configured to pass a current level equal to the original current level through a first transistor of a first type to a control gate of a different transistor of the first type, using current flow through the different transistor of the first type to generate a second control gate voltage level on a control gate of a first transistor of a second type, sampling the second control gate voltage level, retaining the second control gate voltage level, and using the retained second control gate voltage level to generate the other current level proportional to (e.g., equal to) the original current level through a different transistor of the second type.

The output 726 of the TIA 720 might generate a voltage level V_{TIA} indicative of a value of the current level I_{SRC}. The output 726 of the TIA 720 might be selectively connected to an input 742 of an ADC 744 through a switch 740. The switch 740 might represent a FET, which might be an nFET or a pFET. The ADC 744 might be provided to convert the voltage level received from the output 726 of the TIA 720 to a digital value.

The ADC 744 might include a plurality of outputs 752, each configured to output a respective digital signal (e.g., logic high or logic low). Collectively, the plurality of outputs 752 might output a digital value representative of the voltage level V_{TIA} of the output 726 of the TIA 720. The plurality of outputs 752 might provide a binary output vector that is indicative of the function ƒ(Σwᵢxᵢ+b). Additional details of the ADC 744 in accordance with embodiments will be provided subsequently.

Operation of the TIA 720 to produce a voltage level V_{TIA} representative of Σwᵢxᵢ for weights of the first sign and/or the second sign in accordance with embodiments might involve connecting its first input 722 to the node 522 during a first sensing operation of memory cells storing weights of the first sign (e.g., either positive or negative) to receive a first current level I_{SRC} while bypassing the impedance 728, and sampling the resulting first current level from the TIA 720. The process might further involve connecting the first input 722 of the TIA 720 to the node 522 during a second sensing operation of memory cells storing weights of the second sign (e.g., either negative or positive, respectively) to receive a second current level I_{SRC} while bypassing the impedance 728, and sampling the resulting second current level from the TIA 720. The process then might involve isolating the first input 722 of the TIA 720 from the node 522, removing the bypass of the impedance 728, supplying the sampled first current level (e.g., the absolute value of the sampled first current level) to its first input 722, and sinking the sampled second current level (e.g., the absolute value of the sampled second current level) from its first input 722. Further embodiments then might adjust the value of the reference voltage level V_{REF} to adjust the intercept of the activation function to a desired level, e.g., determined by the model, and/or adjust the value of the voltage level VBASE to adjust the lower limit of the activation function to a desired level, e.g., determined by the model. Calculations involving weights of only one sign might involve sampling only a single current level from the TIA 720.

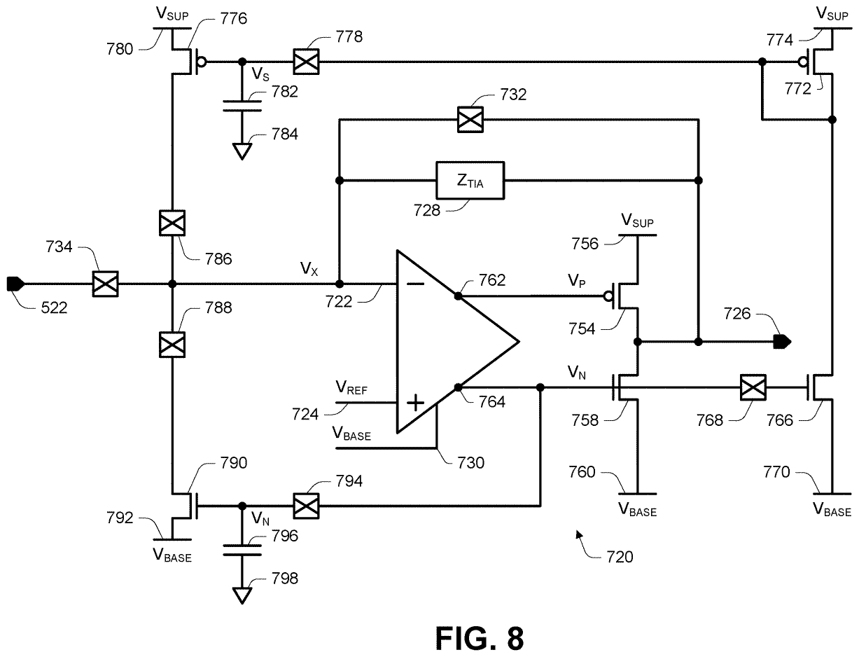

FIG. 8 is a block schematic of a TIA 720 in accordance with an embodiment. In FIG. 8, the TIA 720 might have a first input 722, a second input 724, an output 726, and an impedance (Z_{TIA}) 728 connected between its first input 722 and its output 726. The first input 722 might be an inverted input, and the second input 724 might be a non-inverted input. The second input 724 might be configured to receive the reference voltage level V_{REF}. The TIA 720 might further include a voltage node 730 configured to receive a voltage level VBASE, a base voltage level. The impedance 728 might represent a resistor, and might generally include one or more active or passive circuit elements configured to present a level of resistance (e.g., a predetermined level of resistance) to current flow from the first input 722 to the output 726, e.g., in excess of the conductive lines between the first input 722 and the output 726. In general, a transimpedance amplifier is configured as an operational amplifier (e.g., op-amp) with an impedance connected between its first input and its output. Although not depicted, a capacitance (e.g., a capacitor) might further be connected between the first input 722 and the output 726 in parallel with the impedance 728.

Unconventionally, for various embodiments, the TIA 720 might further include a switch 732 connected between the first input 722 and the output 726 in parallel with the impedance 728, e.g., to permit bypassing the impedance 728. For various embodiments, the first input 722 thus might be selectively directly connected to the output 726, such that current flow preferentially flows through the switch 732 rather than the impedance 728. The switch 732 might represent a FET, which might be an nFET or a pFET.

The first input 722 of the TIA 720 might be selectively connected to the node 522 and thus to the common source 216 through a switch 734 in order to receive a current from the node 522. The switch 734 might represent a FET, which might be an nFET or a pFET. Although the structure and design of the TIA 720, aside from the switch 732, could take a variety of forms recognized in the art, each will generally include a voltage node 756 to inject current into the output 726 and a voltage node 760 to absorb current from the output 726. The voltage node 756 might be configured to receive a voltage level V_{SUP}, e.g., a supply voltage level, and the voltage node 760 might be configured to receive the voltage level VBASE. The voltage level V_{SUP} might be the supply voltage Vcc or other positive externally-supplied or internally-generated voltage level that is higher than the voltage level VBASE. The voltage level V_{SUP} might represent a highest value of a voltage level on the output 726 and the voltage level VBASE might represent a lowest value of a voltage level on the output 726.

The voltage node 756 might be selectively connected to the output 726 through a pFET 754 having its control gate connected to a node 762 of the TIA 720. The node 762 might represent a control node configured to control current flow from the voltage node 756 to the output 726 to maintain the voltage level Vx at the first input 722 equal to the voltage level V_{REF} at the second input 724.

The voltage node 760 might be selectively connected to the output 726 through an nFET 758 having its control gate connected to a node 764 of the TIA 720. The node 764 might represent a control node configured to control current flow from the output 726 to the voltage node 760 to maintain the voltage level Vx at the first input 722 equal to the reference voltage level V_{REF} at the second input 724.

The control gate of the nFET 758 might be selectively connected to an nFET 766 through a switch 768. The switch 768 might be a FET, such as an nFET or pFET. A first source/drain (e.g., source) of the nFET 766 might be connected to a voltage node 770 configured to receive the voltage level VBASE. A second source/drain (e.g., drain) of the nFET 766 might be connected to a first source/drain (e.g., drain) of a pFET 772. A second source/drain (e.g., source) of the pFET 772 might be connected to a voltage node 774 configured to receive the voltage level V_{SUP}. The pFET 772 might be a diode-connected transistor, having its control gate connected to its drain.

The control gate of the pFET 772 might be selectively connected to the control gate of a pFET 776 through a switch 778. The switch 778 might be a FET, such as an nFET or pFET. A capacitance 782 might have a first electrode connected to the control gate of the pFET 776 and a second electrode connected to a voltage node 784. The voltage node 784 might be configured to receive a reference potential, such as 0V, Vss, or ground. The capacitance 782 might be a capacitor, or might generally include one or more active or passive circuit elements configured to present a level of capacitance (e.g., a predetermined level of capacitance) in excess of conductive lines between the switch 778 and the control gate of the pFET 776. A first source/drain (e.g., drain) of the pFET 776 might be selectively connected to the first input 722 of the TIA 720 through a switch 786. The switch 786 might be a FET, such as an nFET or pFET. A second source/drain (e.g., source) of the pFET 776 might be connected to a voltage node 780 configured to receive the voltage level V_{SUP}.

The nFET 766 and the pFET 772 might have the same size, e.g., a same width and length. The nFET 758 and the pFET 776 might have the same size, e.g., a same width and length. The nFET 766 might have a same or different size than the nFET 758. However, to reduce power consumption, the nFET 766 might be sized to be smaller than the nFET 758, e.g., the nFET 766 might have a smaller width and/or length than the nFET 758 to cause its conductance to be lower in response to the same control gate voltage level.

The control gate of the nFET 758 might be selectively connected to an nFET 790 through a switch 794. The switch 794 might be a FET, such as an nFET or pFET. The nFET 758 and the nFET 790 might have the same size, e.g., a same width and length. A first source/drain (e.g., source) of the nFET 790 might be connected to a voltage node 792 configured to receive the voltage level VBASE. A second source/drain (e.g., drain) of the nFET 790 might be selectively connected to the first input 722 of the TIA 720 through a switch 788. The switch 788 might be a FET, such as an nFET or pFET.

A capacitance 796 might have a first electrode connected to the control gate of the nFET 790 and a second electrode connected to a voltage node 798. The voltage node 798 might be configured to receive a reference potential, such as 0V, Vss, or ground. The capacitance 796 might be a capacitor, or might generally include one or more active or passive circuit elements configured to present a level of capacitance (e.g., a predetermined level of capacitance) in excess of conductive lines between the switch 794 and the control gate of the nFET 790.

In operation, the switches 786 and 788 might be open (e.g., FETs deactivated) and the switch 734 might be closed (e.g., a FET activated) during a first sensing operation (e.g., sensing of memory cells storing weights of a first sign) on a block of memory cells in order to pass a first current level of the first sensing operation from the common source to the first input 722 of the TIA 720. The switch 732 might be closed to bypass the impedance 728. In seeking to maintain the voltage level Vx at the first input 722 equal to the reference voltage level V_{REF} at the second input 724, the TIA 720 might be expected to sink an amount of current to the voltage node 760 equal to the first current level sourced to the first input 722 from the node 522. To attain a steady-state current flow through the nFET 758, a control signal from the node 764 might settle to a voltage level configured to produce the desired level of conductance of the nFET 758. Concurrently, a control signal from the node 762 might settle to a voltage level configured to deactivate the pFET 754. The switches 768, 778, and 794 might be open.

To sample the first current level, the switch 768 then might be closed. This might occur after reaching a steady state of current flow through the nFET 758. As a result, the diode-connected pFET 772 might develop a voltage level on its control gate configured to pass the current flowing through the nFET 766 in response to the control gate voltage level of the nFET 758. With the switch 778 closed, this voltage level can be sampled and stored on the capacitance 782. As this voltage level is configured to produce a current level through the pFET 772 equal to the current level through the nFET 766, this voltage level might further be configured to produce a current level through the pFET 776 equal to the first current level through the nFET 758 in response to the ratio of the size of the pFET 776 to the size of the pFET 772 being equal to the ratio of the size of the nFET 758 to the size of the nFET 766. Note that if the ratios are not equal, the current level through the pFET 776 might be expected to be proportional to the current level through the nFET 758, and thus still representative of the first current level received from the node 522. By opening the switch 778, the sampled voltage level might be retained on the control gate of the pFET 776. The switch 768 then might be opened.

A second sensing operation (e.g., sensing of memory cells storing weights of a second sign) then might be performed on the block of memory cells in order to pass a second current level of the second sensing operation from the common source to the first input 722 of the TIA 720. The switches 786 and 788 might be open (e.g., might remain open) and the switch 734 might be closed (e.g., might remain closed). The switches 768, 778, and 794 might be open (e.g., might remain open).

The switch 732 might be closed (e.g., might remain closed) to bypass the impedance 728. In seeking to maintain the voltage level Vx at the first input 722 equal to the reference voltage level V_{REF} at the second input 724, the TIA 720 might be expected to sink an amount of current to the voltage node 760 equal to the second current level sourced to the first input 722 from the node 522. To attain a steady-state current flow through the nFET 758, a control signal from the node 764 might settle to a voltage level configured to produce the desired level of conductance of the nFET 758. Concurrently, a control signal from the node 762 might settle to a voltage level configured to deactivate the pFET 754.

To sample the second current level, the switch 794 then might be closed. This might occur after reaching a steady state of current flow through the nFET 758. With the switch 794 closed, this voltage level can be sampled and stored on the capacitance 796. As this voltage level is configured to produce a current level through the nFET 758 equal to the first current level, this voltage level might further be configured to produce a current level through the nFET 790 equal to the first current level if sized the same. Note that if the sizes are not equal, the current level through the nFET 790 might be expected to be proportional to the current level through the nFET 758, and thus still representative of the first current level received from the node 522. By opening the switch 794, the sampled voltage level might be retained on the control gate of the nFET 790.

The switch 734 then might be opened to isolate the TIA 720 from the node 522, the switch 732 might be opened, and the switches 786 and 788 might be closed to provide a current level to the first input 722 configured to be a combination of the sampled first and second current levels (e.g., equal to a sum of the signed current levels or a sum of +I_{REG(ve+)} and −I_{REG(ve-)}) while current flow from the first input 722 to the output 726 flows through the impedance 728. In this manner, and in accordance with Ohm's law (e.g., V=Z*I), the voltage level of the output 726 of the TIA 720 might be representative of a multiplication partial product of an element of a multiplicand vector and a digit of an element of a multiplier vector for both signed weights of the element of the multiplicand vector.

FIG. 9 is a conceptual depiction of an ADC 744 as a non-binary fully differential successive approximation register analog-to-digital converter (SAR ADC) 902 including a fully differential amplifier (FDA) 904 in accordance with an embodiment.

The FDA 904 is depicted to include a first input 906, e.g., a non-inverting input, as the input 742 of the ADC 744, and a second input 908, e.g., an inverting input, configured to receive a first reference voltage level V_{REF}. The first reference voltage level V_{REF} might be the reference potential, e.g., Vss, ground or 0V. The FDA 904 might further have a first output 916, e.g., a non-inverting output, for providing a first output voltage level Vₒₚ, and a second output 918, e.g., an inverting output, for providing a second output voltage level Vₒₙ. The common mode voltage level V_{CM} might be between (e.g., half-way between) the first output voltage level Vₒₚ and the second output voltage level Vₒₙ.

The FDA 904 might be connected to a voltage node 910 configured to receive a second reference voltage level V_{refp}, a voltage node 912 configured to receive a third reference voltage level V_{refn}, and a voltage node 914 configured to receive a common mode voltage level V_{CM}. The third reference voltage level V_{refn} might correspond to a lowest voltage level of an output of the FDA 904, and might be lower than the second reference voltage level V_{refp}, which might correspond to a highest voltage level of an output of the FDA 904. The common mode voltage level V_{CM} might be between (e.g., half-way between) the second reference voltage level V_{refp} and the third reference voltage level V_{refn}. For example, the value of V_{CM} might equal (V_{refp}+V_{refn})/2.

The SAR ADC 902 is depicted to include a first input 926, e.g., a non-inverting input, connected to the first output 916 of the FDA 904 and configured to receive the first output voltage level Vₒₚ of the FDA 904 as its first input voltage level Vᵢₙₚ. The SAR ADC 902 is further depicted to include a second input 928, e.g., an inverting input, connected to the second output 918 of the FDA 904 and configured to receive the second output voltage level Vₒₙ of the FDA 904 as its second input voltage level Vᵢₙₙ. The SAR ADC 902 might further have a set of outputs as the outputs 752 of the ADC 744. The SAR ADC 902 might be connected to a voltage node 930 configured to receive the second reference voltage level V_{refp}, to a voltage node 932 configured to receive the third reference voltage level V_{refn}, and to a voltage node 934 configured to receive the common mode voltage level V_{CM}.

The FDA 904 might be configured to generate the output voltage levels Vₒₙ and Vₒₚ such that (Vₒₙ+Vₒₚ)/2 is equal to V_{CM}, and the difference Vₒₚ−Vₒₙ is proportional to, and has a higher magnitude than, the difference V_{TIA}−V_{REF}. The SAR ADC 902 might be configured to generate a binary output vector indicative of the difference Vᵢₙₚ−Vᵢₙₙ (e.g., equal to the difference Vₒₚ−Vₒₙ and proportional to the difference V_{TIA}−V_{REF}).

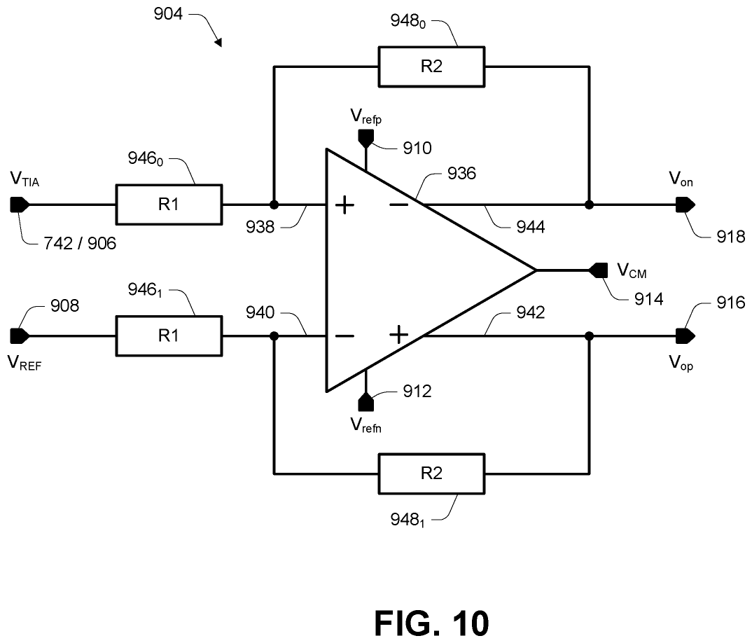

FIG. 10 is a block schematic of a fully-differential amplifier 904 in accordance with an embodiment. The FDA 904 might include an operational amplifier (op-amp) 936 having a first input (e.g., a non-inverting input) 938, a second input (e.g., an inverting input) 940, a first output (e.g., a non-inverting output) 942, and a second output (e.g., an inverting output) 944. The first output 942 of the op-amp 936 might correspond to the first output 916 of the FDA 904 providing the first output voltage level Vₒₚ, and the second output 944 of the op-amp 936 might correspond to the second output 918 of the FDA 904 providing the second output voltage level Vₒₙ. The op-amp 936 might further be connected to the voltage node 910 configured to receive the second reference voltage level V_{refp}, to the voltage node 912 configured to receive the third reference voltage level V_{refn}, and to the voltage node 914 configured to receive the common mode voltage level V_{CM}.

The first input 938 of the op-amp 936 might be connected to the first input 906 of the FDA 904, and thus to the input 742 of the ADC 744, through a first resistor 9460, and the second input 940 of the op-amp 936 might be connected to the second input 908 of the FDA 904 through a second resistor 9461. The first resistor 9460 and the second resistor 9461 might have a same resistance level R1. A third resistor 9480, might be connected between the first input 938 of the op-amp 936 and the second output 944 of the op-amp 936, and a fourth resistor 9481 might be connected between the second input 940 of the op-amp 936 and the first output 942 of the op-amp 936. The third resistor 9480 and the fourth resistor 9481 might have a same resistance level R2, which might be the same or different than the resistance level R1. A gain of the FDA 904 might correspond to the value R2/R1.

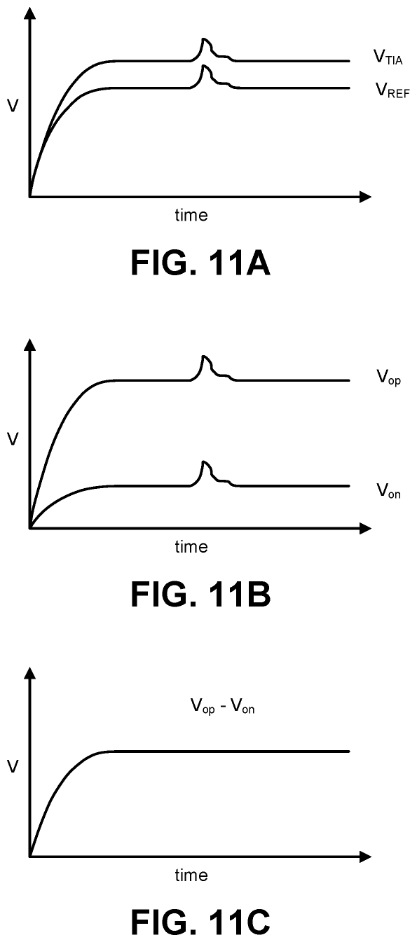

FIGS. 11A-11C are example graphs of possible inputs and outputs of a fully-differential amplifier (FDA) and a corresponding relationship of the outputs in accordance with an embodiment. Analog signals, e.g., voltage or current levels, might be subject to signal aberrations, e.g., noise or spikes, caused by external factors, e.g., changes in supply voltage levels. As the general nature of analog-to-digital conversion of an analog signal provides an output vector representative of the magnitude of the analog signal, the occurrence of such signal aberrations could result in an erroneous output vector that is not representative of its intended value.

The use of an FDA can mitigate the effects of signal aberrations in the incoming analog signals. In particular, noise or spikes caused by external factors might affect both input signals in a similar manner. For example, FIG. 11A depicts a signal aberration occurring in each of the input voltage signals to an FDA, e.g., V_{TIA} and V_{REF}. As depicted in FIG. 11B, the signal aberrations carry through to the output voltage signals of the FDA, e.g., Vₒₚ and Vₒₙ. However, because a difference between both voltage signals Vₒₚ−Vₒₙ might be used by a SAR ADC in determining its output vector, the signal aberrations of the input voltage signals might be canceled out, such as depicted in FIG. 11C.

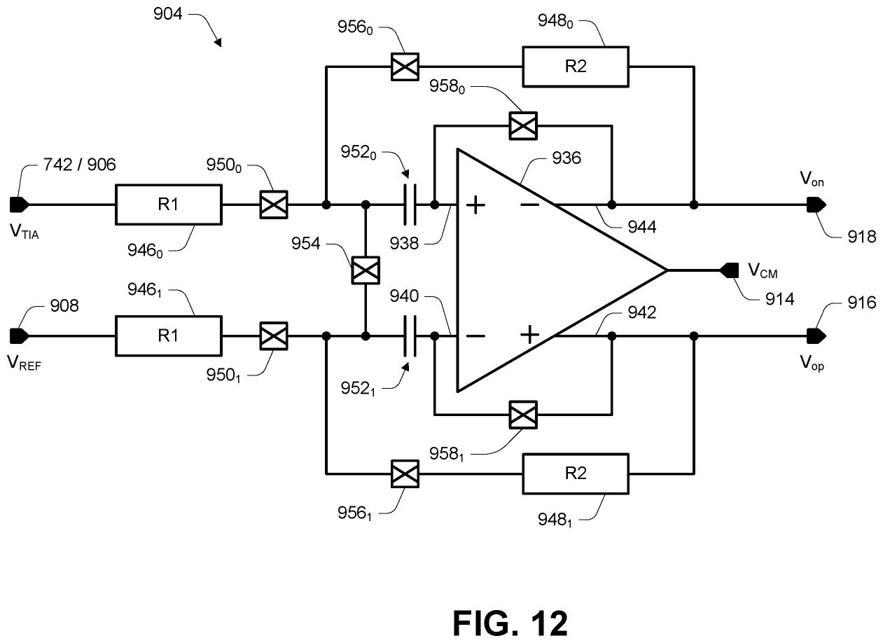

FIG. 12 is a block schematic of a fully-differential amplifier (FDA) in accordance with another embodiment. The FDA 904 of FIG. 12 might include an operational amplifier (op-amp) 936 having a first input (e.g., a non-inverting input) 938, a second input (e.g., an inverting input) 940, a first output (e.g., a non-inverting output) 942, and a second output (e.g., an inverting output) 944. The first output 942 of the op-amp 936 might correspond to the first output 916 of the FDA 904 providing the first output voltage level Vₒₚ, and the second output 944 of the op-amp 936 might correspond to the second output 918 of the FDA 904 providing the second output voltage level Vₒₙ. The op-amp 936 might further be connected to the voltage node 914 configured to receive the common mode voltage level V_{CM}. For clarity, connections of the op-amp 936 to the voltage nodes 910 and 912 are not depicted in FIG. 12.

The first input 938 of the op-amp 936 might be connected to a first electrode of a capacitor 9520. A second electrode of the capacitor 9520 might be selectively connected to the first input 906 of the FDA 904, and thus to the input 742 of the ADC 744, through a switch 9500 and a first resistor 9460. The second input 940 of the op-amp 936 might be connected to a first electrode of a capacitor 9521. A second electrode of the capacitor 9521 might be selectively connected to the second input 908 of the FDA 904 through a switch 9501 and a second resistor 9461. The first capacitor 9520 and the second capacitor 9521 might have a same capacitance level. The first resistor 9460 and the second resistor 9461 might have a same resistance level R1.

A third resistor 9480 might have a first end selectively connected to the second electrode of the capacitor 9520 through a switch 9560, and a second end connected to the second output 944 of the op-amp 936. A fourth resistor 9481 might have a first end selectively connected to the second electrode of the capacitor 9521 through a switch 9561, and a second end connected to the first output 942 of the op-amp 936. The third resistor 9480 and the fourth resistor 9481 might have a same resistance level R2, which might be the same or different than the resistance level R1. A gain of the FDA 904 might correspond to the value R2/R1.

A switch 954 might be connected between the second electrode of the capacitor 9520 and the second electrode of the capacitor 9521. A switch 9580 might be connected between the first input 938 of the op-amp 936 and the second output 944 of the op-amp 936, and a switch 9581 might be connected between the second input 940 of the op-amp 936 and the first output 942 of the op-amp 936. The switches 9500, 9501, 954, 9560, 9561, 9580, and 9581 each might represent a field-effect transistor, and each might be an nFET or a pFET. During sampling, switches 9500, 9501, 9560, and 9561 might be closed (e.g., activated), while switches 954, 9580, and 9581 might be open (e.g., deactivated). Subsequently, e.g., after reaching a steady-state condition, offset might be canceled for an amplification phase during conversion to a binary output vector by a SAR ADC. For this, switches 9500, 9501, 9560, and 9561 might be open (e.g., deactivated), while switches 954, 9580, and 9581 might be closed (e.g., activated).

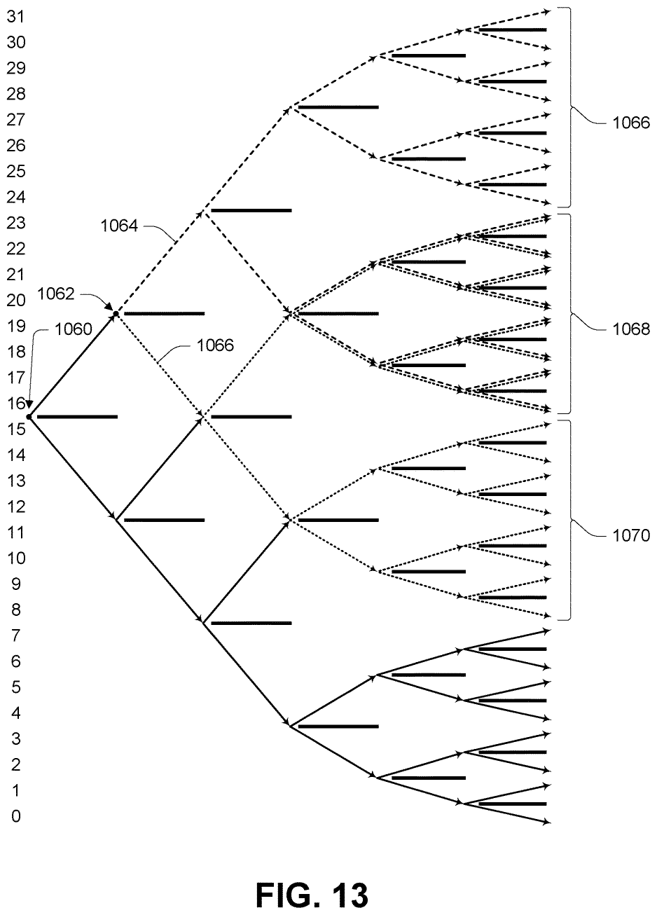

FIG. 13 is an example decision tree of a non-binary SAR ADC as could be used with embodiments. The example of FIG. 13 might represent the decision tree for a 5-digit binary output using a 6-step non-binary conversion. The example of FIG. 13 might include weights for each step as provided in Table 1.

TABLE 1

| Step | 1 | 2 | 3 | 4 | 5 | 6 |
|---|---|---|---|---|---|---|
| Weight at k^{th} step - p(k) | 16 | 4 | 4 | 4 | 2 | 1 |

The weights p(k) might generally have values between 1 and 2\hat{ }(N−1), and might further have integer values between 1 and 2\hat{ }(N−1), wherein N equals the number of digits of the binary output of the SAR ADC. The weight p(1) might be equal to 2\hat{ }(N−1) and the weight p(M) might be greater than or equal to 1, and the remaining weights p(2) through p(M−1) might each be less than p(1) and greater than or equal to p(M), wherein M equals the number of steps of the non-binary conversion of the SAR ADC. The sum of all weights p(1) through p(M) might be equal to 2\hat{ }N−1. The weights p(k) might further represent a non-binary progression of values. For example, for at least one value of k from 1 to M−1, p(k)/2+p(k+1). The weights p(k) for values of k from 2 to M might represent relative capacitance levels of a first number of capacitors (e.g., a first capacitor to an (M−1)^{th} capacitor) of an array of capacitors of the non-binary SAR ADC having M capacitors for generating an M-step non-binary conversion, wherein the last capacitor (e.g., the M^{th} capacitor) of the array of capacitors typically assumes a relative capacitance level of 1.

A non-binary SAR ADC having a decision tree of FIG. 13 might generate a 6-digit non-binary output value that might resolve into a 5-digit binary output vector. FIG. 13 demonstrates the ability of a non-binary SAR ADC to resolve to a correct output even if all decision points are not evaluated correctly. For example, at the decision point 1060, the first digit of the non-binary output value might evaluate to a logical 1, leading to the decision point 1062. If the second digit of the non-binary output value evaluates to a logical 1 at decision point 1062, the possible paths from that point might be represented by the long-dashed line 1064, and if the second digit of the non-binary output value evaluates to a logical 0 at decision point 1062, the possible paths from that point might be represented by the short-dashed line 1066. As can be seen with reference to FIG. 13, evaluating to a logical 1 at decision point 1062 might provide coverage for the ranges 1066 (e.g., 24-31 base 10) and 1068 (e.g., 16-23 base 10), while evaluating to a logical 0 at decision point 1062 might provide coverage for the ranges 1068 (e.g., 16-23 base 10) and 1070 (e.g., 8-15 base 10). In this manner, coverage might be provided for the range 1068 regardless of whether the decision point 1062 evaluated correctly. This behavior differs from a binary SAR ADC in which each decision point must generally evaluate correctly in order to obtain the correct output. The non-binary SAR ADC is thus more forgiving of erroneous evaluations.

In general, a non-binary SAR ADC might be configured for a number (M) of steps of non-binary conversion that is greater than a number (N) of digits of its output vector. The non-binary SAR ADC might have a first array of capacitors of M capacitors connected in parallel to a non-inverting input of a comparator and a second array of capacitors of M capacitors connected in parallel to an inverting input of the comparator. Each capacitor of the first array of capacitors might correspond to a capacitor of the second array of capacitors, and each pair of corresponding capacitors each might have a same capacitance value. The weights p(k) of each step of non-binary conversion might generally represent relative capacitance values of a first number (e.g., M−1) of capacitors of the arrays of capacitors of the non-binary SAR ADC. A last capacitor in each array of capacitors typically assumes a relative capacitance level of 1.

A resulting value (e.g., in base 10) of the decision tree of FIG. 13 might be described by Equation 4:

$${Output}_{10} = 16 + ( ( {D}_{1} * 2 ) - 1 ) * 4 + ( ( {D}_{2} * 2 ) - 1 ) * 4 + ( ( {D}_{3} * 2 ) - 1 ) * 4 + ( ( {D}_{4} * 2 ) - 1 ) * 2 + ( ( {D}_{5} * 2 ) - 1 ) * 1 + ( {D}_{6} - 1 ) \qquad Eq . 4$$

Where:
Dₖ is the respective value (e.g., 0 or 1) determined at the k^{th} step of the non-binary SAR ADC conversion.

More generally, the resulting value in base 10 for a non-binary SAR-ADC configured for a number (M) of steps of non-binary conversion and a number (N) of digits of its output vector might be represented by Equations 5 and 6:

$${Output}_{10} = p ( 1 ) + [ {\sum }_{k = 1}^{M - 1} ( ( 2 * {D}_{k} ) - 1 ) * p ( k + 1 ) ] + ( {D}_{M} - 1 ) \qquad Eq . 5$$

Where:
Dₖ is the respective value (e.g., 0 or 1) determined at the k^{th} step of the non-binary SAR ADC conversion, with k=1 to M; and
p(k) is the weight for the k^{th} step of the non-binary SAR ADC; and

$${\sum }_{k = 1}^{M} p ( k ) = ( {2}^{N} - 1 ) \qquad Eq . 6$$

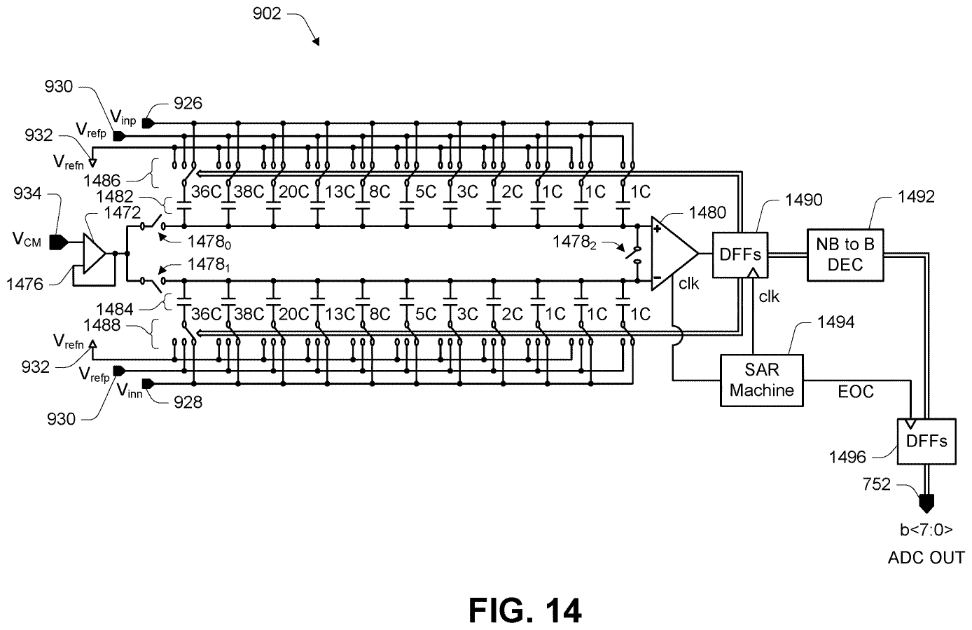

FIG. 14 is a block schematic of a non-binary SAR ADC 902 in accordance with an embodiment. The SAR ADC 902 might include a first array of capacitors 1482 (e.g., a first plurality of capacitors 1482) connected in parallel to a first input (e.g., a non-inverting input) of a comparator 1480, e.g., each having a first electrode (e.g., a top plate) connected to the first input of the comparator 1480. A second electrode (e.g., a bottom plate) of each capacitor 1482 of the first array of capacitors 1482 each might be selectively connected to one of the voltage node 930 configured to receive the second reference voltage level V_{refp}, the voltage node 932 configured to receive the third reference voltage level V_{refn}, or the first input 926 of the SAR ADC 902 configured to receive the first input voltage level Vᵢₙₚ using a corresponding set of switches 1486. For some embodiments, one of the capacitors 1482 (e.g., a capacitor 1482 having a lowest capacitance of the first array of capacitors 1482) might have its second electrode selectively connected to one of the voltage node 930 configured to receive the second reference voltage level V_{refp}, or the first input 926 of the SAR ADC 902 configured to receive the first input voltage level Vᵢₙₚ, and might be devoid of a selective connection to the voltage node 932 configured to receive the third reference voltage level V_{refn}. Each switch 1486 might represent a multiplexer (e.g., 3:1 or 2:1) responsive to one or more control signals. Although each capacitor 1482 associated with a switch 1486 is depicted to be a single capacitor, one or more of the capacitors 1482 could represent multiple capacitors connected in series and/or parallel to provide the desired capacitance level.

The SAR ADC 902 might further include a second array of capacitors 1484 (e.g., a second plurality of capacitors 1484) connected in parallel to a second input (e.g., an inverting input) of the comparator 1480, e.g., each having a first electrode (e.g., a top plate) connected to the second input of the comparator 1480. Each capacitor 1482 of the first array of capacitors 1482 might correspond to a respective capacitor 1484 of the second array of capacitors 1484, e.g., in a one-to-one relationship, and each capacitor 1482 of the first array of capacitors 1482 might have a same capacitance level as its respective capacitor 1484 of the second array of capacitors 1484. A second electrode (e.g., a bottom plate) of each capacitor 1484 of the second array of capacitors 1484 each might be selectively connected to one of the voltage node 930 configured to receive the second reference voltage level V_{refp}, the voltage node 932 configured to receive the third reference voltage level V_{refn}, or the second input 928 of the SAR ADC 902 configured to receive the second input voltage level Vᵢₙₙ using a corresponding set of switches 1488. For some embodiments, one of the capacitors 1484 (e.g., a capacitor 1484 having a lowest capacitance of the second array of capacitors 1484) might have its second electrode selectively connected to one of the voltage node 930 configured to receive the second reference voltage level V_{refp}, or the second input 928 of the SAR ADC 902 configured to receive the second input voltage level Vᵢₙₙ, and might be devoid of a selective connection to the voltage node 932 configured to receive the third reference voltage level V_{refn}. Each switch 1488 might represent a multiplexer (e.g., 3:1 or 2:1) responsive to one or more control signals. Although each capacitor 1484 associated with a switch 1488 is depicted to be a single capacitor, one or more of the capacitors 1484 could represent multiple capacitors connected in series and/or parallel to provide the desired capacitance level.

The first array of capacitors 1482 and the second array of capacitors 1484 might represent a SAR ADC configured to provide an 11-step non-binary conversion (e.g., M=11) to resolve to an 8-digit binary vector (e.g., N=8). For one embodiment, they might include non-binary weights (e.g., relative capacitance levels) for each step as provided in Table 2.

TABLE 2

| Step | | 1 | 2 | 3 | 4 | 5 | 6 | 7 | 8 | 9 | 10 | 11 |
|---|---|---|---|---|---|---|---|---|---|---|---|---|
| Weight at k^{th} step | p(k) | 128 | 36 | 38 | 20 | 13 | 8 | 5 | 3 | 2 | 1 | 1 |
| Correction margin at | q(k) | 56 | 16 | 14 | 8 | 5 | 3 | 2 | 1 | 1 | 0 | 0 |
| k^{th} step | | | | | | | | | | | | |
| % correction margin | q(k)/p(k) | 44 | 44 | 37 | 40 | 39 | 38 | 40 | 33 | 50 | 0 | 0 |
| at k^{th} step | (%) | | | | | | | | | | | |

Such non-binary weights might provide significant percent correction margins through the 9^{th} step. Each of the arrays of capacitors 1482/1484 might include M capacitors, or 11 capacitors in this example. Ten of the capacitors of each of the arrays of capacitors 1482/1484 in this example might have relative capacitance levels corresponding to the p(k) values for steps 2-11 times a base capacitance level C, where C is some positive value of Farads, and the last capacitor of the array of capacitors typically assumes the value of 1C. In this example, three capacitors of each of the arrays of capacitors 1482/1484 might have a capacitance level of 1C, one capacitor of each of the arrays of capacitors 1482/1484 might have a capacitance level of 2C, one capacitor of each of the arrays of capacitors 1482/1484 might have a capacitance level of 3C, one capacitor of each of the arrays of capacitors 1482/1484 might have a capacitance level of 5C, one capacitor of each of the arrays of capacitors 1482/1484 might have a capacitance level of 8C, one capacitor of each of the arrays of capacitors 1482/1484 might have a capacitance level of 13C, one capacitor of each of the arrays of capacitors 1482/1484 might have a capacitance level of 20C, one capacitor of each of the arrays of capacitors 1482/1484 might have a capacitance level of 38C, and one capacitor of each of the arrays of capacitors 1482/1484 might have a capacitance level of 36C. These capacitors might have a total capacitance level of 128C, or 2\hat{ }(N−1)*C for each array of capacitors 1482/1484. Given that p(1) generally might be equal to 2\hat{ }(N−1), the sum of the p(k) values for this example might equal 2\hat{ }N−1.

An op-amp 1472 might have a first input connected to the voltage node 934 configured to receive the common mode voltage level V_{CM}, and a feedback loop 1476 connected between an output of the op-amp 1472 and a second input of the op-amp 1472, e.g., to function as a unity gain amplifier. The output of the op-amp 1472 might be selectively connected to the first input of the comparator 1480 through a switch 1478₀, and selectively connected to the second input of the comparator 1480 through a switch 1478₁. Alternatively, the voltage node 934 might be connected to the switches 1478₀ and 1478₁ without the use of the op-amp 1472, e.g., directly connected. A switch 1478₂ might selectively connect the first input of the comparator 1480 to the second input of the comparator 1480. The switches 1478₀, 1478₁, and 1478₂ each might represent a field-effect transistor, and each might be an nFET or a pFET.

An output of the comparator 1480 might be connected to an input of D Flip Flops (DFFs) 1490. The DFFs 1490 might provide control signals to the switches 1486 and to the switches 1488 in a manner to be described later. An output of the DFFs 1490 might be provided to an input of a non-binary to binary decoder (NB to B DEC) 1492, and an output of the NB to B December 1492 might be provided to an input of DFFs 1496. An output of the DFFS 1496 might correspond to the outputs 752 of the SAR ADC 902. The NB to B December 1492 might be configured to convert an M-digit non-binary vector from the DFFs 1490 to an N-digit binary vector to the DFFs 1496. The NB to B December 1492 might be configured as full-adder logic in manners understood in the relevant art to perform the conversion of Equation 5 in a binary environment.

A SAR machine 1494 (e.g., logic) might be in communication with the comparator 1480, the DFFs 1490, and the DFFs 1496 to control the transfer of digits from the comparator 1480 to the DFFs 1490, to control the latching of digits in the DFFs 1490, and to control the latching of digits in the DFFs 1496.

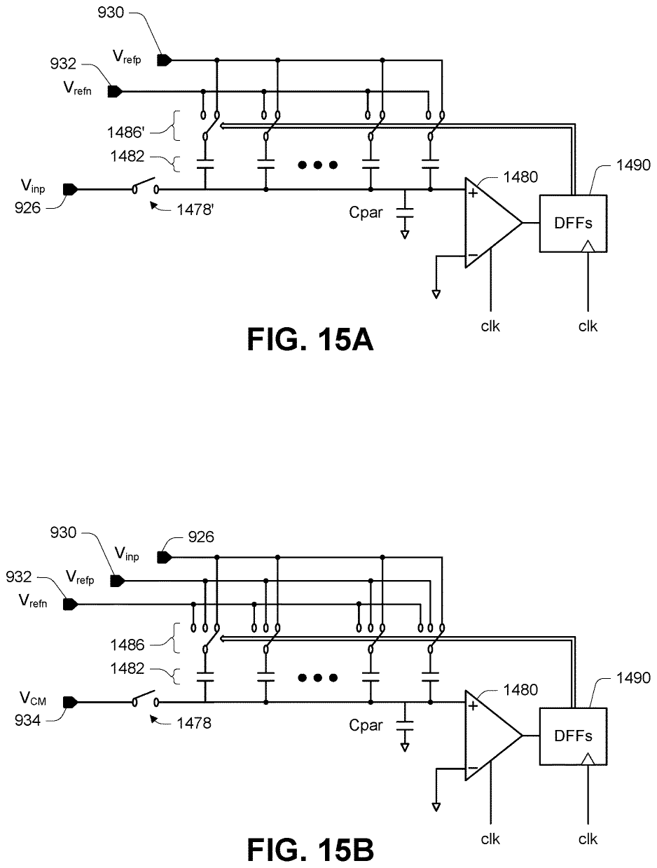

The configuration of the SAR ADC 902 of FIG. 13 differs from traditional SAR ADC configurations. In particular, various embodiments provide for sampling the input voltage levels Vᵢₙₙ and Vᵢₙₚ at the bottom plates of their respective array of capacitors 1482 and 1484, respectively. FIGS. 15A and 15B are used to discuss this difference.

FIG. 15A is a block schematic of a portion of a C-DAC of the related art utilizing top plate sampling of the input voltage levels, e.g., applying an input voltage level to the top plates of an array of capacitors. For clarity, only one input voltage level, e.g., Vᵢₙₚ, is depicted, but the connections for the other input voltage level, e.g., Vᵢₙₙ, could be a mirror image of the connections to the non-inverting input of the comparator 1480.

FIG. 15A depicts a first array of capacitors 1482 connected in parallel to a first input (e.g., a non-inverting input) of a comparator 1480, e.g., each having a first electrode (e.g., a top plate) connected to the first input of the comparator 1480. A second electrode (e.g., a bottom plate) of each capacitor 1482 of the first array of capacitors 1482 each might be selectively connected to one of the voltage node 930 configured to receive the second reference voltage level V_{refp} or the voltage node 932 configured to receive the third reference voltage level V_{refn}, using a corresponding set of switches 1486′. The voltage node 926 (e.g., the first input 926 of the SAR ADC 902) configured to receive the first input voltage level Vᵢₙₚ might be selectively connected to the first input of the comparator 1480 through a switch 1478′. The connections to the first input of the comparator 1480 might have an inherent parasitic capacitance Cₚₐᵣ, while the array of capacitors 1482 might have a combined capacitance C_{DAC}.

With this configuration, there is no scaling of the input voltage level, but the full range of the DAC might be scaled by the value C_{DAC}/(C_{DAC}+Cₚₐᵣ). In this manner, higher levels of the parasitic capacitance Cₚₐᵣ might be expected to lead to higher levels of gain error.

FIG. 15B is a block schematic of a portion of a C-DAC in accordance with an embodiment utilizing bottom plate sampling of the input voltage levels, e.g., applying an input voltage level to the bottom plates of an array of capacitors. For clarity, only one input voltage level, e.g., Vᵢₙₚ, is depicted, but the connections for the other input voltage level, e.g., Vᵢₙₙ, could be a mirror image of the connections to the non-inverting input of the comparator 1480 as depicted in FIG. 14.

FIG. 15B depicts a first array of capacitors 1482 connected in parallel to a first input (e.g., a non-inverting input) of a comparator 1480, e.g., each having a first electrode (e.g., a top plate) connected to the first input of the comparator 1480. A second electrode (e.g., a bottom plate) of each capacitor 1482 of the first array of capacitors 1482 each might be selectively connected to one of the voltage node 930 configured to receive the second reference voltage level V_{refp}, the voltage node 932 configured to receive the third reference voltage level V_{refn}, or the voltage node 926 configured to receive the first input voltage level Vᵢₙₚ, using a corresponding set of switches 1486. The voltage node 934 configured to receive the common mode voltage level V_{CM} might be selectively connected to the first input of the comparator 1480 through a switch 1478. The connections to the first input of the comparator 1480 might have an inherent parasitic capacitance Cₚₐᵣ, while the array of capacitors 1482 might have a combined capacitance C_{DAC}.

With this configuration, the input voltage level might be scaled by the value C_{DAC}/(C_{DAC}+Cₚₐᵣ), while the full range of the DAC also might be scaled by the value C_{DAC}/(C_{DAC}+Cₚₐᵣ). In this manner, the configuration might be immune from gain error, regardless of the level of the parasitic capacitance Cₚₐᵣ.

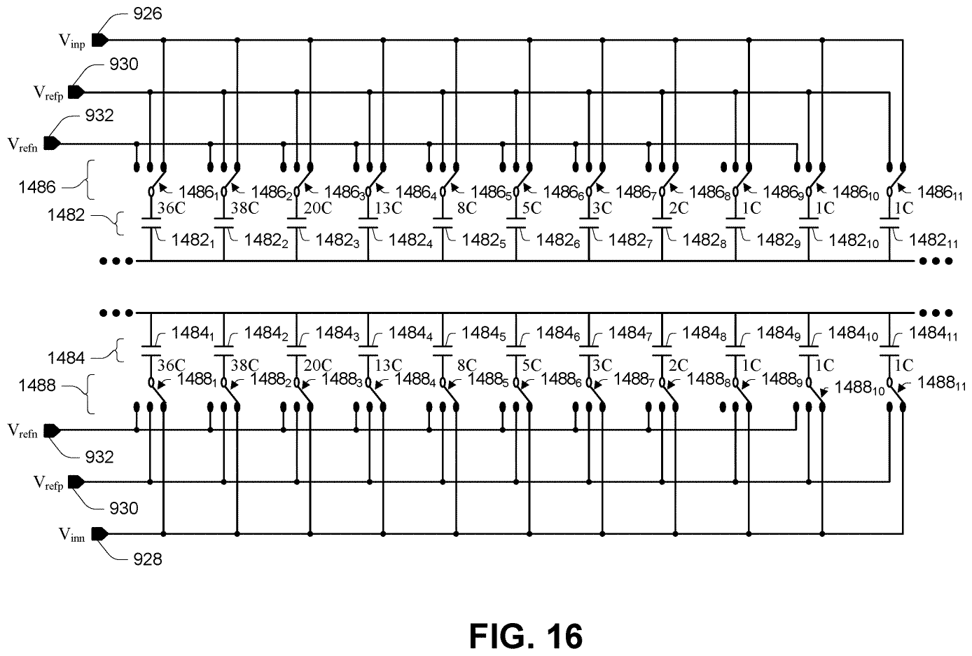

FIG. 16 is a schematic of an array of capacitors of a digital-to-analog converter (C-DAC) of the SAR ADC of FIG. 14 for use in describing its operation. The C-DAC of FIG. 16 might correspond to a SAR ADC configured to provide an 11-step non-binary conversion (e.g., M=11) to resolve to an 8-digit binary vector (e.g., N=8), and might use the weights as provided in Table 2. As depicted in FIG. 16, capacitors 1482₁₁ and 1484₁₁ each might have a relative capacitance level of 1C, capacitors 1482₁₀ and 1484₁₀ each might have a relative capacitance level of 1C, capacitors 1482₉ and 1484₉ each might have a relative capacitance level of 1C, capacitors 1482₈ and 1484₈ each might have a relative capacitance level of 2C, capacitors 1482₇ and 1484₇ each might have a relative capacitance level of 3C, capacitors 1482₆ and 1484₆ each might have a relative capacitance level of 5C, capacitors 1482₅ and 1484₅ each might have a relative capacitance level of 8C, capacitors 1482₄ and 1484₄ each might have a relative capacitance level of 13C, capacitors 1482₃ and 1484₃ each might have a relative capacitance level of 20C, capacitors 1482₂ and 1484₂ each might have a relative capacitance level of 38C, and capacitors 1482₁ and 1484₁ each might have a relative capacitance level of 36C. Although the first array of capacitors 1482 and the second array of capacitors 1484 are depicted to be arranged in a particular order, the orders could each be rearranged.

The switch 1486₁ might selectively connect the second electrode of the capacitor 1482₁ to one of the voltage node 926 configured to receive the first input voltage level Vᵢₙₚ, the voltage node 930 configured to receive the second reference voltage level V_{refp}, or the voltage node 932 configured to receive the third reference voltage level V_{refn}; the switch 1486₂ might selectively connect the second electrode of the capacitor 1482₂ to one of the voltage node 926, the voltage node 930, or the voltage node 932; the switch 1486₃ might selectively connect the second electrode of the capacitor 1482₃ to one of the voltage node 926, the voltage node 930, or the voltage node 932; the switch 1486₄ might selectively connect the second electrode of the capacitor 1482₄ to one of the voltage node 926, the voltage node 930, or the voltage node 932; the switch 1486₅ might selectively connect the second electrode of the capacitor 1482₅ to one of the voltage node 926, the voltage node 930, or the voltage node 932; the switch 1486₆ might selectively connect the second electrode of the capacitor 1482₆ to one of the voltage node 926, the voltage node 930, or the voltage node 932; the switch 1486₇ might selectively connect the second electrode of the capacitor 1482₇ to one of the voltage node 926, the voltage node 930, or the voltage node 932; the switch 1486₈ might selectively connect the second electrode of the capacitor 1482₈ to one of the voltage node 926, the voltage node 930, or the voltage node 932; the switch 1486₉ might selectively connect the second electrode of the capacitor 1482₉ to one of the voltage node 926, the voltage node 930, or the voltage node 932; the switch 1486₁₀ might selectively connect the second electrode of the capacitor 1482₁₀ to one of the voltage node 926, the voltage node 930, or the voltage node 932; and the switch 1486₁₁ might selectively connect the second electrode of the capacitor 1482₁₁ to one of the voltage node 926 or the voltage node 930 (or to one of the voltage node 926, the voltage node 930, or the voltage node 932)

The switch 1488₁ might selectively connect the second electrode of the capacitor 1484₁ to one of the voltage node 928 (e.g., the second input 928 of the SAR ADC 902) configured to receive the second input voltage level Vᵢₙₙ, the voltage node 930 configured to receive the second reference voltage level V_{refp}, or the voltage node 932 configured to receive the third reference voltage level V_{refn}; the switch 1488₂ might selectively connect the second electrode of the capacitor 1484₂ to one of the voltage node 928, the voltage node 930, or the voltage node 932; the switch 1488₃ might selectively connect the second electrode of the capacitor 1484₃ to one of the voltage node 928, the voltage node 930, or the voltage node 932; the switch 1488₄ might selectively connect the second electrode of the capacitor 1484₄ to one of the voltage node 928, the voltage node 930, or the voltage node 932; the switch 1488₅ might selectively connect the second electrode of the capacitor 1484₅ to one of the voltage node 928, the voltage node 930, or the voltage node 932; the switch 1488₆ might selectively connect the second electrode of the capacitor 1484₆ to one of the voltage node 928, the voltage node 930, or the voltage node 932; the switch 1488₇ might selectively connect the second electrode of the capacitor 1484₇ to one of the voltage node 928, the voltage node 930, or the voltage node 932; the switch 1488₈ might selectively connect the second electrode of the capacitor 1484₈ to one of the voltage node 928, the voltage node 930, or the voltage node 932; the switch 1488₉ might selectively connect the second electrode of the capacitor 1484₉ to one of the voltage node 928, the voltage node 930, or the voltage node 932; the switch 1488₁₀ might selectively connect the second electrode of the capacitor 1484₁₀ to one of the voltage node 928, the voltage node 930, or the voltage node 932; and the switch 1488₁₁ might selectively connect the second electrode of the capacitor 1484₁₁ to one of the voltage node 928 or the voltage node 930 (or to one of the voltage node 928, the voltage node 930, or the voltage node 932).

In operation, during a sampling phase, the common mode voltage level V_{CM} might be applied to the first electrodes (e.g., top plates) of each capacitor 1482 of the first array of capacitors 1482 and to the non-inverting input of the comparator 1480, and to the first electrodes (e.g., top plates) of each capacitor 1484 of the second array of capacitors 1484 and to the inverting input of the comparator 1480. For example, with reference to FIG. 14, the switches 1478₀ and 1478₁ might be activated (e.g., closed). For some embodiments, the switch 1478₂ also might be activated (e.g., closed) while applying the common mode voltage level V_{CM}. At the end of the sampling phase, the switches 1478₀, 1478₁, and 1478₂ then might be deactivated (e.g., open) to permit the first electrodes of the capacitors 1482 and the first electrodes of the capacitors 1484 to electrically float (e.g., at the common mode voltage level V_{CM}).

Also during the sampling phase, the first input voltage level Vᵢₙₚ might be applied to the second electrodes (e.g., bottom plates) of each capacitor 1482 of the first array of capacitors 1482 through appropriate activation of the switches 1486 (e.g., to connect the capacitors 1482 to the voltage node 926), and the second input voltage level Vᵢₙₙ might be applied to the second electrodes (e.g., bottom plates) of each capacitor 1484 of the second array of capacitors 1484 through appropriate activation of the switches 1488 (e.g., to connect the capacitors 1484 to the voltage node 928). At the end of sampling phase, a voltage difference of (Vᵢₙₚ−V_{CM}) might be stored between the first electrodes (e.g., top plates) and the second electrodes (e.g., bottom plates) of each capacitor 1482 of the first array of capacitors 1482, and a voltage difference of (Vᵢₙₙ−V_{CM}) might be stored between the first electrodes (e.g., top plates) and the second electrodes (e.g., bottom plates) of each capacitor 1484 of the second array of capacitors 1484.

In a first conversion cycle, the capacitors 1482₁-1482₁₁ might have their second electrodes (e.g., bottom plates) connected to the voltage node 930 (V_{refp}) through appropriate activation of the switches 1486₁-1486₁₁, respectively. In response, the voltage potential of the first electrodes (e.g., top plates) of each capacitor 1482 of the first array of capacitors 1482 and the non-inverting input of the comparator 1480 might transition from V_{CM} initially to (V_{CM}−Vᵢₙₚ+V_{refp}) (e.g., so that the stored voltage of the first array of capacitors 1482 is still at (Vᵢₙₚ−V_{CM}). Similarly, the capacitors 1484₁-1484₁₁ might have their second electrodes (e.g., bottom plates) connected to the voltage node 930 (V_{refp}) through appropriate activation of the switches 1488₁-1488₁₁, respectively. In response, the voltage potential of the first electrodes (e.g., top plates) of each capacitor 1484 of the second array of capacitors 1484 and the inverting input of the comparator 1480 might transition from V_{CM} initially to (V_{CM}−Vᵢₙₙ+V_{refp}) (e.g., so that the stored voltage of the second array of capacitors 1484 is still at (Vᵢₙₙ−V_{CM})). At this point, the differential voltage between the non-inverting input and inverting input of the comparator 1480 might be −(Vᵢₙₚ−Vᵢₙₙ) and the common mode level of the non-inverting input and inverting input of the comparator 1480 might be (V_{CM}+½V_{refp}). Following application of these voltage levels, an output value of the comparator 1480 might be latched in the DFFs 1490 as a first digit, e.g., a most significant bit (MSB), of the 11-digit non-binary output value. Latching of this and subsequent digits might be in response to the SAR machine 1494.

In response to the first digit of the 11-digit non-binary output value having a first value (e.g., logical 1) indicative of the non-inverting input of the comparator 1480 receiving a higher voltage level than the inverting input of the comparator 1480, the capacitor 1482₁ might have its second electrode connected to the voltage node 932 (V_{refn}) through appropriate activation of the switch 1486₁, and in response to the first digit of the 11-digit non-binary output value having a second value (e.g., logical 0) indicative of the non-inverting input of the comparator 1480 receiving a lower voltage level than the inverting input of the comparator 1480, the capacitor 1484₁ might have its second electrode connected to the voltage node 932 (V_{refn}) through appropriate activation of the switch 1488₁. Following the selected action, the output value of the comparator 1480 might be latched in the DFFs 1490 as a second digit, e.g., a less significant bit, of the 11-digit non-binary output value.

In response to the second digit of the 11-digit non-binary output value having the first value indicative of the non-inverting input of the comparator 1480 receiving a higher voltage level than the inverting input of the comparator 1480, the capacitor 1482₂ might have its second electrode connected to the voltage node 932 through appropriate activation of the switch 1486₂, and in response to the second digit of the 11-digit non-binary output value having the second value indicative of the non-inverting input of the comparator 1480 receiving a lower voltage level than the inverting input of the comparator 1480, the capacitor 1484₂ might have its second electrode connected to the voltage node 932 through appropriate activation of the switch 1488₂. Following the selected action, the output value of the comparator 1480 might be latched in the DFFs 1490 as a third digit of the 11-digit non-binary output value.

In response to the third digit of the 11-digit non-binary output value having the first value indicative of the non-inverting input of the comparator 1480 receiving a higher voltage level than the inverting input of the comparator 1480, the capacitor 1482₃ might have its second electrode connected to the voltage node 932 through appropriate activation of the switch 1486₃, and in response to the third digit of the 11-digit non-binary output value having the second value indicative of the non-inverting input of the comparator 1480 receiving a lower voltage level than the inverting input of the comparator 1480, the capacitor 1484₃ might have its second electrode connected to the voltage node 932 through appropriate activation of the switch 1488₃. Following the selected action, the output value of the comparator 1480 might be latched in the DFFs 1490 as a fourth digit of the 11-digit non-binary output value.

In response to the fourth digit of the 11-digit non-binary output value having the first value indicative of the non-inverting input of the comparator 1480 receiving a higher voltage level than the inverting input of the comparator 1480, the capacitor 1482₄ might have its second electrode connected to the voltage node 932 through appropriate activation of the switch 1486₄, and in response to the fourth digit of the 11-digit non-binary output value having the second value indicative of the non-inverting input of the comparator 1480 receiving a lower voltage level than the inverting input of the comparator 1480, the capacitor 1484₄ might have its second electrode connected to the voltage node 932 through appropriate activation of the switch 1488₄. Following the selected action, the output value of the comparator 1480 might be latched in the DFFs 1490 as a fifth digit of the 11-digit non-binary output value.

In response to the fifth digit of the 11-digit non-binary output value having the first value indicative of the non-inverting input of the comparator 1480 receiving a higher voltage level than the inverting input of the comparator 1480, the capacitor 1482₅ might have its second electrode connected to the voltage node 932 through appropriate activation of the switch 1486₅, and in response to the fifth digit of the 11-digit non-binary output value having the second value indicative of the non-inverting input of the comparator 1480 receiving a lower voltage level than the inverting input of the comparator 1480, the capacitor 1484₅ might have its second electrode connected to the voltage node 932 through appropriate activation of the switch 1488₅. Following the selected action, the output value of the comparator 1480 might be latched in the DFFs 1490 as a sixth digit of the 11-digit non-binary output value.

In response to the sixth digit of the 11-digit non-binary output value having the first value indicative of the non-inverting input of the comparator 1480 receiving a higher voltage level than the inverting input of the comparator 1480, the capacitor 1482₆ might have its second electrode connected to the voltage node 932 through appropriate activation of the switch 1486₆, and in response to the sixth digit of the 11-digit non-binary output value having the second value indicative of the non-inverting input of the comparator 1480 receiving a lower voltage level than the inverting input of the comparator 1480, the capacitor 1484₆ might have its second electrode connected to the voltage node 932 through appropriate activation of the switch 1488₆. Following the selected action, the output value of the comparator 1480 might be latched in the DFFs 1490 as a seventh digit of the 11-digit non-binary output value.

In response to the seventh digit of the 11-digit non-binary output value having the first value indicative of the non-inverting input of the comparator 1480 receiving a higher voltage level than the inverting input of the comparator 1480, the capacitor 1482₇ might have its second electrode connected to the voltage node 932 through appropriate activation of the switch 1486₇, and in response to the seventh digit of the 11-digit non-binary output value having the second value indicative of the non-inverting input of the comparator 1480 receiving a lower voltage level than the inverting input of the comparator 1480, the capacitor 1484₇ might have its second electrode connected to the voltage node 932 through appropriate activation of the switch 1488₇. Following the selected action, the output value of the comparator 1480 might be latched in the DFFs 1490 as an eighth digit of the 11-digit non-binary output value.

In response to the eighth digit of the 11-digit non-binary output value having the first value indicative of the non-inverting input of the comparator 1480 receiving a higher voltage level than the inverting input of the comparator 1480, the capacitor 1482₈ might have its second electrode connected to the voltage node 932 through appropriate activation of the switch 1486₈, and in response to the eighth digit of the 11-digit non-binary output value having the second value indicative of the non-inverting input of the comparator 1480 receiving a lower voltage level than the inverting input of the comparator 1480, the capacitor 1484₈ might have its second electrode connected to the voltage node 932 through appropriate activation of the switch 1488₈. Following the selected action, the output value of the comparator 1480 might be latched in the DFFs 1490 as a ninth digit of the 11-digit non-binary output value.

In response to the ninth digit of the 11-digit non-binary output value having the first value indicative of the non-inverting input of the comparator 1480 receiving a higher voltage level than the inverting input of the comparator 1480, the capacitor 1482₉ might have its second electrode connected to the voltage node 932 through appropriate activation of the switch 1486₉, and in response to the ninth digit of the 11-digit non-binary output value having the second value indicative of the non-inverting input of the comparator 1480 receiving a lower voltage level than the inverting input of the comparator 1480, the capacitor 1484₉ might have its second electrode connected to the voltage node 932 through appropriate activation of the switch 1488₉. Following the selected action, the output value of the comparator 1480 might be latched in the DFFs 1490 as a tenth digit of the 11-digit non-binary output value.

In response to the tenth digit of the 11-digit non-binary output value having the first value indicative of the non-inverting input of the comparator 1480 receiving a higher voltage level than the inverting input of the comparator 1480, the capacitor 1482₁₀ might have its second electrode connected to the voltage node 932 through appropriate activation of the switch 1486₁₀, and in response to the tenth digit of the 11-digit non-binary output value having the second value indicative of the non-inverting input of the comparator 1480 receiving a lower voltage level than the inverting input of the comparator 1480, the capacitor 1484₁₀ might have its second electrode connected to the voltage node 932 through appropriate activation of the switch 1488₁₀. Following the selected action, the output value of the comparator 1480 might be latched in the DFFs 1490 as an eleventh digit of the 11-digit non-binary output value. The 11 digits of the 11-digit non-binary output value held by the DFFs 1490 might be provided to the non-binary to binary decoder 1492, e.g., in response to the SAR machine 1494.

It can be seen that Equation 5 defining the value of the binary output of the SAR ADC in base 10 could be expressed as a function of the relative capacitance levels of the arrays of capacitors of the SAR ADC. An example of such an expression is provided in Equation 7:

$${Output}_{10} = 2 \hat{} ( N - 1 ) + [ {\sum }_{k = 1}^{M - 1} ( ( 2 * {D}_{k} ) - 1 ) * C ( k ) ] + ( {D}_{M} - 1 ) \qquad Eq . 7$$

Where:
N is the number of digits of the binary output vector;
Dₖ is the k^{th} digit of the M-digit non-binary output value, with k=1 to M; and
C(k) is the relative capacitance level of the k^{th} capacitor of one of the arrays of capacitors, e.g., relative to the capacitance level of the capacitor having the lowest capacitance level of the array of capacitors (e.g., the M^{th} capacitor).

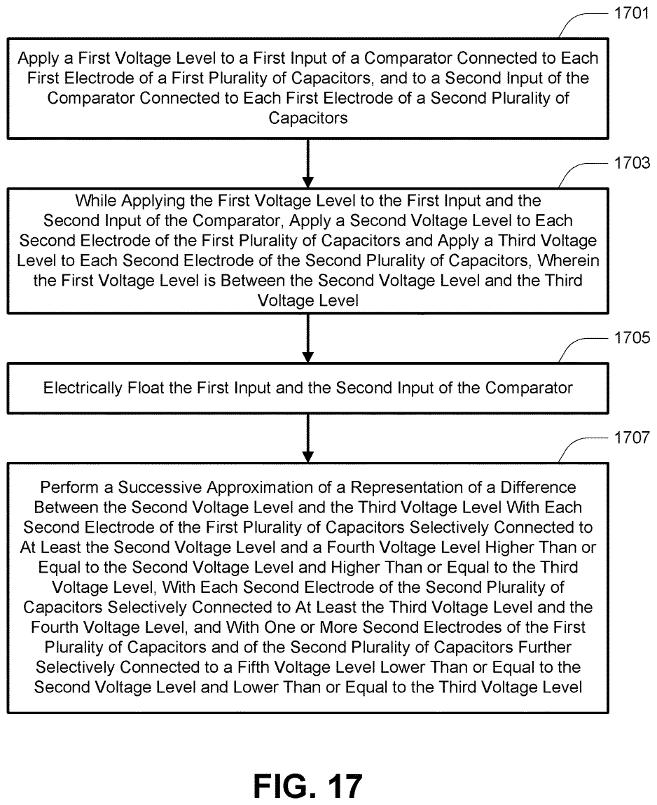

FIG. 17 is a flowchart of a method of generating a representation of a differential input in accordance with an embodiment. The method might represent actions associated with a sensing operation of a memory, e.g., a sensing operation associated with the determination of a multiplication partial product of an element of a multiplicand vector and a digit of an element of a multiplier vector, wherein the differential input might be representative of a voltage level indicative of a value of the multiplication partial product. The method might be in the form of computer-readable instructions, e.g., stored to the instruction registers 128. Such computer-readable instructions might be executed by a controller, e.g., the control logic 116, to cause the relevant components of the memory to perform the method.

At 1701, a first voltage level might be applied to a first input of a comparator connected to each first electrode of a first plurality of capacitors, and to a second input of the comparator connected to each first electrode of a second plurality of capacitors. For example, the common mode voltage level V_{CM} from voltage node 934 might be applied to both inputs of the comparator 1480, and to the first electrodes of the capacitors 1482₁-1482₁₁ and 1484₁-1484₁₁, by activating the switches 1478₀, 1478₁, and 1478₂. Deactivating the switches 1478₀, 1478₁, and 1478₂ then might cause the first electrodes of the capacitors 1482₁-1482₁₁ and 1484₁-1484₁₁, and both inputs of the comparator 1480, to be electrically floating.

At 1703, while applying the first voltage level to the first input and the second input of the comparator, a second voltage level might be applied to each second electrode of the first plurality of capacitors, and a third voltage level might be applied to each second electrode of the second plurality of capacitors. The first voltage level might be between the second voltage level and the third voltage level. For example, the first input voltage level Vᵢₙₚ from the voltage node 926 might be applied to the second electrodes of the capacitors 1482₁-1482₁₁ through appropriate activation of the switches 1486₁-1486₁₁, respectively, and the second input voltage level Vᵢₙₙ from the voltage node 928 might be applied to the second electrodes of the capacitors 1484₁-1484₁₁ through appropriate activation of the switches 1488₁-1488₁₁, respectively. The first input voltage level Vᵢₙₚ might be higher than the common mode voltage level V_{CM} and the second input voltage level Vᵢₙₙ might be lower than the common mode voltage level V_{CM}. Alternatively, the first input voltage level Vᵢₙₚ might be lower than the common mode voltage level V_{CM} and the second input voltage level Vᵢₙₙ might be higher than the common mode voltage level V_{CM}.

At 1705, The first input and the second input of the comparator might be electrically floated. For example, deactivating the switches 1478₀, 1478₁, and 1478₂ might cause the first electrodes of the capacitors 1482₁-1482₁₁ and 1484₁-1484₁₁, and both inputs of the comparator 1480, to be electrically floating. This might include continuing to apply the second voltage level to each second electrode of the first plurality of capacitors, and continuing to apply the third voltage level to each second electrode of the second plurality of capacitors.

At 1707, a successive approximation of a representation of a difference between the second voltage level and the third voltage level (which might be a representation of a voltage level at the first input 906 of the FDA 904) might be performed with each second electrode of the first plurality of capacitors selectively connected to at least the second voltage level and a fourth voltage level higher than or equal to the second voltage level and higher than or equal to the third voltage level, with each second electrode of the second plurality of capacitors selectively connected to at least the third voltage level and the fourth voltage level, and with at least one or more second electrodes of the first plurality of capacitors and of the second plurality of capacitors further selectively connected to a fifth voltage level lower than or equal to the second voltage level and lower than or equal to the third voltage level. For example, a successive approximation might be performed with each of the capacitors 1482₁-1482₁₁ selectively connected to the first input voltage level Vᵢₙₚ and to the second reference voltage level V_{refp} that is higher than or equal to both the first input voltage level Vᵢₙₚ and the second input voltage level Vᵢₙₙ, with each of the capacitors 1484₁-1484₁₁ selectively connected to the second input voltage level Vᵢₙₙ and to the second reference voltage level V_{refp}, and with the capacitors 1482₁-1482₁₀ and the capacitors 1484₁-1484₁₀ further selectively connected to the third reference voltage level V_{refn} that is lower than or equal to both the first input voltage level Vᵢₙₚ and the second input voltage level Vᵢₙₙ. The successive approximation might be performed in a manner as described with reference to FIGS. 14 and 16.

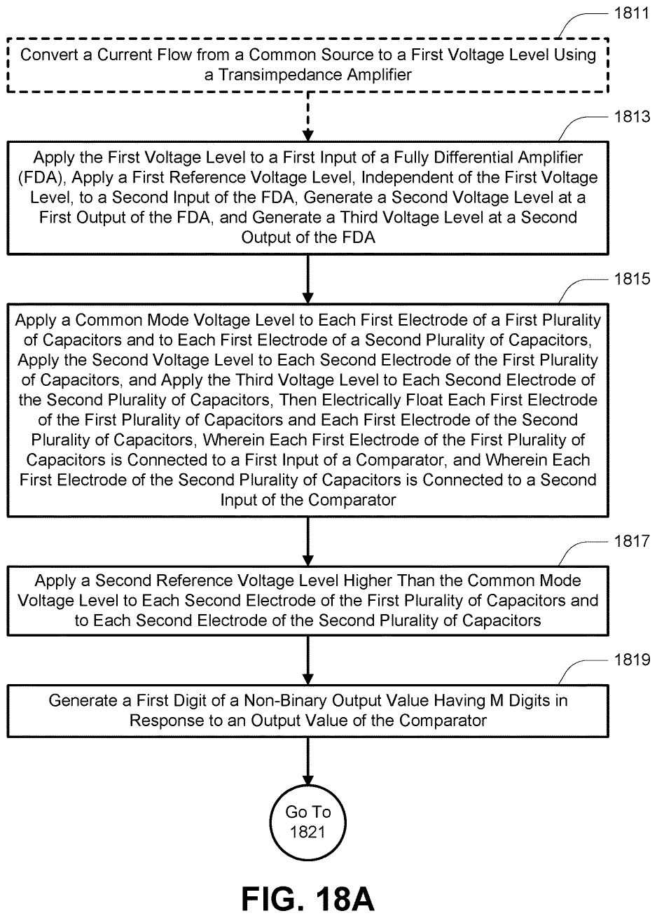

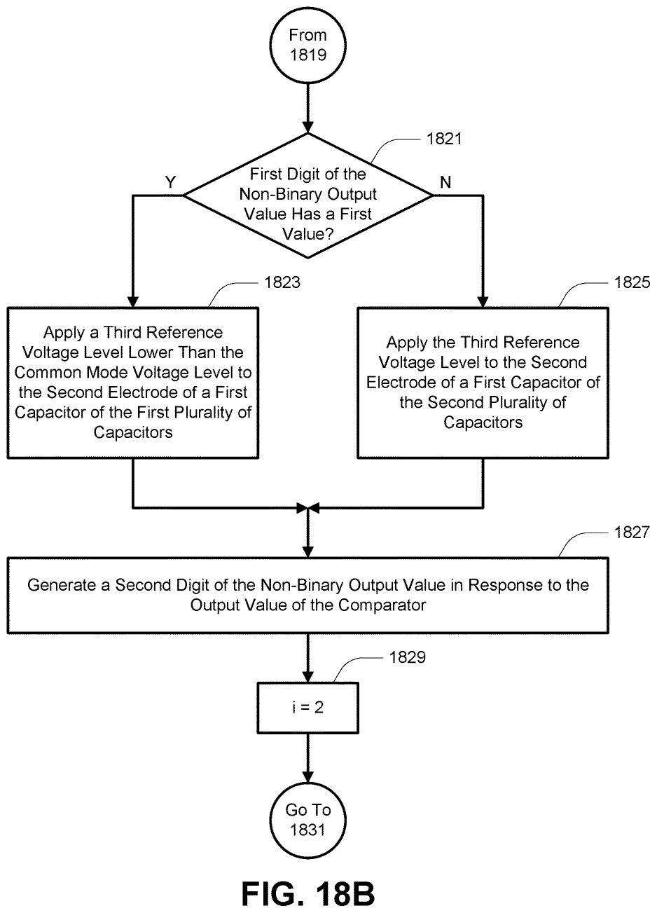

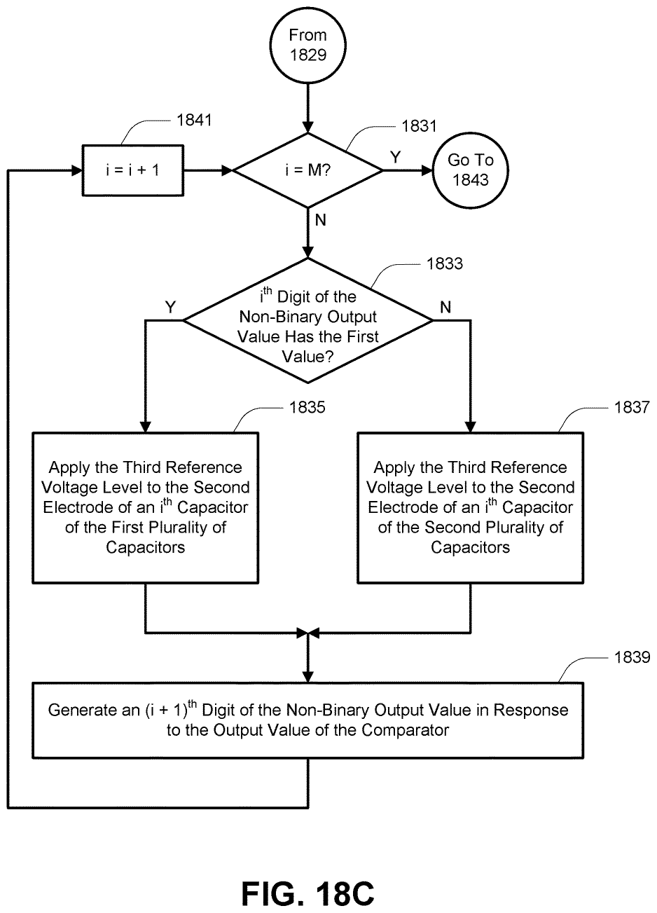

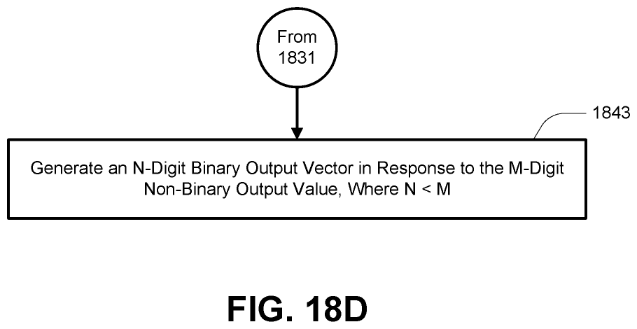

FIGS. 18A-18D are a flowchart of a method of generating a representation of a differential input in accordance with an embodiment. The method might represent actions associated with a sensing operation of a memory, e.g., a sensing operation associated with the determination of a multiplication partial product of an element of a multiplicand vector and a digit of an element of a multiplier vector, wherein the differential input might be representative of a voltage level indicative of a value of the multiplication partial product. The method might be in the form of computer-readable instructions, e.g., stored to the instruction registers 128. Such computer-readable instructions might be executed by a controller, e.g., the control logic 116, to cause the relevant components of the memory to perform the method.

Optionally, at 1811, a current flow from a common source of a memory might be converted to a first voltage level using a transimpedance amplifier. For example, a sensing operation on an array of memory cells such as depicted and described with reference to FIG. 5 might be representative of a multiplication partial product of an element of a multiplicand vector and a digit of an element of a multiplier vector. The resulting current flow I_{SRC} from the node 522 might be converted to a voltage level V_{TIA} using a TIA 720 as discussed with reference to FIG. 7.

At 1813, the first voltage level might be applied to a first input of a fully differential amplifier (FDA). A first reference voltage level, independent of the first voltage level, might be applied to a second input of the FDA. A second voltage level might be generated at a first output of the FDA, and a third voltage level might be generated at a second output of the FDA, e.g., in response to the input first voltage level and first reference voltage level. For example, the voltage level V_{TIA} might be applied to the first input 906 of the FDA 904, the first reference voltage level V_{REF} might be applied to the second input 908 of the FDA 904, the first output voltage level Vₒₚ might be generated at the first output 916 of the FDA 904, and the second output voltage level Vₒₙ might be generated at the second output 918 of the FDA 904. The difference between the first output voltage level Vₒₚ and the second output voltage level Vₒₙ might be indicative of a value of the voltage level V_{TIA}.

At 1815, a common mode voltage level might be applied to each first electrode of a first plurality of capacitors and to each first electrode of a second plurality of capacitors, the second voltage level might be applied to each second electrode of the first plurality of capacitors, and the third voltage level might be applied to each second electrode of a second plurality of capacitors, then electrically float each first electrode of the first plurality of capacitors and each first electrode of a second plurality of capacitors. The common mode voltage level, the second voltage level, and the third voltage level might be applied concurrently at 1815 prior to electrically floating each first electrode of the first plurality of capacitors and each first electrode of a second plurality of capacitors. Each first electrode of the first plurality of capacitors might be connected to a first input of a comparator, and each first electrode of the second plurality of capacitors might be connected to a second input of the comparator. For example, the common mode voltage level V_{CM} from voltage node 934 might be applied to both inputs of the comparator 1480, and to the first electrodes of the capacitors 1482₁-1482₁₁ and 1484₁-1484₁₁, by activating the switches 1478₀, 1478₁, and 1478₂; the first output voltage level Vₒₚ (e.g., the first input voltage level Vᵢₙₚ) might be applied to the second electrodes of the capacitors 1482₁-1482₁₁ through appropriate activation of the switches 1486₁-1486₁₁, respectively; and the second output voltage level Vₒₙ (e.g., the second input voltage level Vᵢₙₙ) might be applied to the second electrodes of the capacitors 1484₁-1484₁₁ through appropriate activation of the switches 1488₁-1488₁₁, respectively. Deactivating the switches 1478₀, 1478₁, and 1478₂ then might cause the first electrodes of the capacitors 1482₁-1482₁₁ and 1484₁-1484₁₁, and both inputs of the comparator 1480, to be electrically floating.

At 1817, in a first conversion cycle, a second reference voltage level higher than the common mode voltage level might be applied to each second electrode of the first plurality of capacitors and to each second electrode of the second plurality of capacitors. For example, the capacitors 1482₁-1482₁₁ might have their second electrodes connected to the voltage node 930 (V_{refp}) through appropriate activation of the switches 1486₁-1486₁₁, respectively, and the capacitors 1484₁-1484₁₁ might have their second electrodes connected to the voltage node 930 (V_{refp}) through appropriate activation of the switches 1488₁-1488₁₁, respectively.

At 1819, a first digit of a non-binary output value having M digits might be generated in response to an output value of the comparator. The value of M might be equal to the number of capacitors of the first plurality of capacitors, or the number of capacitors of the second plurality of capacitors. The value of the first digit of the non-binary output value might be equal to the output value of the comparator. At 1821, it might be determined whether the first digit of the non-binary output value has a first value. The first value (e.g., logical 1) might be indicative of an output value of the comparator indicating that the first input of the comparator is receiving a higher voltage level than the second input of the comparator. A second value (e.g., logical 0) might be indicative of an output value of the comparator indicating that the first input of the comparator is receiving a lower voltage level than the second input of the comparator.

Continuing with the example, the first digit of the non-binary output value might have the first value in response to the first output voltage level Vₒₚ (e.g., the first input voltage level Vᵢₙₚ) being higher than the second output voltage level Vₒₙ (e.g., the second input voltage level Vᵢₙₙ) due to the capacitive coupling driving the non-inverting input of the comparator 1480 higher than the inverting input of the comparator 1480. Conversely, the comparator 1480 might not have the first value (e.g., might have the second value) in response to the first output voltage level Vₒₚ (e.g., the first input voltage level Vᵢₙₚ) being lower than the second output voltage level Vₒₙ (e.g., the second input voltage level Vᵢₙₙ) due to the capacitive coupling driving the inverting input of the comparator 1480 higher than the non-inverting input of the comparator 1480. In this example, M might equal 11 (eleven).

At 1823, in response to determining that the first digit of the non-binary output value has the first value, a third reference voltage level lower than the common mode voltage level might be applied to the second electrode of a first capacitor of the first plurality of capacitors. Alternatively, at 1825, in response to determining that the first digit of the non-binary output value does not have the first value, the third reference voltage level might be applied to the second electrode of a first capacitor of the second plurality of capacitors. For example, in response to determining that the first digit of the non-binary output value has the first value, the third reference voltage level V_{refn} might be applied to the second electrode of the capacitor 1482₁ and in response to determining that the first digit of the non-binary output value does not have the first value, the third reference voltage level V_{refn} might be applied to the second electrode of the capacitor 1484₁.

At 1827, a second digit of the non-binary output value might be generated in response to an output value of the comparator. The value of the second digit of the non-binary output value might be equal to the output value of the comparator. At 1829, a value i might be set to 2 (two), and at 1831, it might be determined whether the value i is equal to M, e.g., equal to the number of digits of the non-binary output value. In response to the value i not being equal to M, e.g., being less than M, the process might proceed to 1833, and in response to the value i being equal to M, the process might proceed to 1843.

At 1833, it might be determined whether an i^{th} digit of the non-binary output value has the first value. At 1835, in response to determining that the i^{th} digit of the non-binary output value has the first value, the third reference voltage level might be applied to the second electrode of an i^{th} capacitor of the first plurality of capacitors. Alternatively, at 1837, in response to determining that the i^{th} digit of the non-binary output value does not have the first value, the third reference voltage level might be applied to the second electrode of an i^{th} capacitor of the second plurality of capacitors. For example, in response to determining that the i^{th} digit of the non-binary output value has the first value, the third reference voltage level V_{refn} might be applied to the second electrode of the i^{th} capacitor of the first plurality of capacitors 1482, e.g., capacitor 1482i, and in response to determining that the i^{th} digit of the non-binary output value does not have the first value, the third reference voltage level V_{refn} might be applied to the second electrode of the i^{th} capacitor of the second plurality of capacitors 1484, e.g., capacitor 1484j.

At 1839, an (i+1)^{th} digit of the non-binary output value might be generated in response to the output value of the comparator. The value of the (i+1)^{th} digit of the non-binary output value might be equal to the output value of the comparator. At 1841, the value i might be incremented by 1 (one) and the process might return to 1831. Although this process is described to increment the value of i by 1 in each loop, it could be thought of as simply repeating the process of 1833-1839 for each value of i from 2 through M−1 before proceeding to 1843.

At 1843, in response to the value i being equal to M at 1831, an N-digit binary output vector might be generated in response to the M-digit non-binary output value. The value of N might be less than the value of M. The N-digit binary output vector might be generated using a decision tree approach, such as depicted in FIG. 13. Alternatively, the N-digit binary output vector might be generated using Equation 7 (or Equation 5) along with the digit values of the M-digit non-binary output value and the weights (e.g., relative capacitance values) of the capacitors 1482₁-1482₁₀ and 1484₁-1484₁₀.

Note that the first electrodes of the first plurality of capacitors and the second plurality of capacitors might remain electrically floating in the method of FIGS. 18A-18D from the initiation in 1815 until the last digit of the non-binary output value can be generated in 1839. Similarly, each second electrode of the first plurality of capacitors might continue to receive the second reference voltage level until the last digit of the non-binary output value can be generated in 1839 unless switched to the third reference voltage level at 1823 or 1835, each second electrode of the second plurality of capacitors might continue to receive the second reference voltage level until the last digit of the non-binary output value can be generated in 1839 unless switched to the third reference voltage level at 1825 or 1837, and each second electrode of the first plurality of capacitors or the second plurality of capacitors that is switched to the third reference voltage level at 1823, 1825, 1835, or 1837 might continue to receive the third reference voltage level until the last digit of the non-binary output value can be generated in 1839.

### CONCLUSION

Although specific embodiments have been illustrated and described herein, it will be appreciated by those of ordinary skill in the art that any arrangement that is calculated to achieve the same purpose might be substituted for the specific embodiments shown. Many adaptations of the embodiments will be apparent to those of ordinary skill in the art. Accordingly, this application is intended to cover any adaptations or variations of the embodiments.

What is claimed is:

1. A successive approximation register analog-to-digital converter (SAR ADC), comprising:
a first voltage node configured to receive a common mode voltage level;
a second voltage node configured to receive a first input voltage level;
a third voltage node configured to receive a second input voltage level, wherein the common mode voltage level is between the first input voltage level and the second input voltage level;
a fourth voltage node configured to receive a first reference voltage level higher than or equal to the first input voltage level and higher than or equal to the second input voltage level;
a fifth voltage node configured to receive a second reference voltage level lower than the first reference voltage level, lower than or equal to the first input voltage level, and lower than or equal to the second input voltage level;
a comparator having a first input selectively connected to the first voltage node, a second input selectively connected to the first voltage node, and an output;
a first array of capacitors, wherein each capacitor of the first array of capacitors has a first electrode connected to the first input of the comparator, and a second electrode selectively connected to one of at least the second voltage node and the fourth voltage node; and
a second array of capacitors, wherein each capacitor of the second array of capacitors has a first electrode connected to the second input of the comparator, and a second electrode selectively connected to one of at least the third voltage node and the fourth voltage node;
wherein the second electrodes of at least one capacitor of the first array of capacitors are each selectively connected to one of the second voltage node, the fourth voltage node, and the fifth voltage node; and
wherein the second electrodes of at least one capacitor of the second array of capacitors are each selectively connected to one of the third voltage node, the fourth voltage node, and the fifth voltage node.

2. The SAR ADC of claim 1, wherein the second electrodes of all but one capacitor of the first array of capacitors are each selectively connected to one of the second voltage node, the fourth voltage node, and the fifth voltage node, and wherein the second electrodes of all but one capacitor of the second array of capacitors are each selectively connected to one of the third voltage node, the fourth voltage node, and the fifth voltage node.

3. The SAR ADC of claim 1, wherein the second electrodes of all capacitors of the first array of capacitors are each selectively connected to one of the second voltage node, the fourth voltage node, and the fifth voltage node, and wherein the second electrodes of all capacitors of the second array of capacitors are each selectively connected to one of the third voltage node, the fourth voltage node, and the fifth voltage node.

4. The SAR ADC of claim 1, wherein the SAR ADC is configured to generate an M-digit non-binary output value representative of a difference between the first input voltage level and the second input voltage level wherein the first array of capacitors comprises M capacitors, and wherein the second array of capacitors comprises M capacitors.

5. The SAR ADC of claim 4, wherein the SAR ADC is further configured to generate an N-digit binary output vector in response to the M-digit non-binary output value, wherein Nis less than M.

6. The SAR ADC of claim 5, wherein a capacitance level of each capacitor of the first array of capacitors is a respective multiple of C, wherein C is a positive value of Farads, and wherein a sum of the capacitance level of all capacitors of the first array of capacitors is equal to 2\hat{ }(N−1)*C.

7. The SAR ADC of claim 6, wherein a capacitance level of each capacitor of the second array of capacitors is equal to the capacitance level of its respective capacitor of the first array of capacitors.

8. The SAR ADC of claim 6, wherein the capacitance level of at least one capacitor of the first array of capacitors is equal to one times C.

9. An apparatus, comprising:
a successive approximation register analog-to-digital converter (SAR ADC) comprising:
a comparator having a first input, a second input, and an output;
a first array of capacitors, wherein each capacitor of the first array of capacitors has a first electrode connected to the first input of the comparator, and a second electrode;
a second array of capacitors, wherein each capacitor of the second array of capacitors has a first electrode connected to the second input of the comparator, and a second electrode; and
a controller configured to cause the apparatus to:
apply a first voltage level to the first input of the comparator and to the second input of the comparator, then electrically float the first input of the comparator and the second input of the comparator;
while applying the first voltage level to the first input of the comparator and to the second input of the comparator, apply a second voltage level to each second electrode of the first plurality of capacitors and apply a third voltage level to each second electrode of the second plurality of capacitors, wherein the first voltage level is between the second voltage level and the third voltage level; and
perform a successive approximation of a representation of a difference between the second voltage level and the third voltage level with each second electrode of the first plurality of capacitors selectively connected to at least the second voltage level and a fourth voltage level higher than or equal to the second voltage level and higher than or equal to the third voltage level, with each second electrode of the second plurality of capacitors selectively connected to at least the third voltage level and the fourth voltage level, and with one or more second electrodes of the first plurality of capacitors and of the second plurality of capacitors further selectively connected to a fifth voltage level lower than or equal to the second voltage level and lower than or equal to the third voltage level.

10. The apparatus of claim 9, wherein the controller being configured to cause the apparatus to perform the successive approximation with each second electrode of the first plurality of capacitors selectively connected to at least the second voltage level and the fourth voltage level, with each second electrode of the second plurality of capacitors selectively connected to at least the third voltage level and the fourth voltage level, and with one or more second electrodes of the first plurality of capacitors and of the second plurality of capacitors further selectively connected to the fifth voltage level comprises the controller being configured to cause the apparatus to perform the successive approximation with all but one capacitor of the first plurality of capacitors having their second electrodes selectively connected to the second voltage level, the fourth voltage level, and the fifth voltage level, and all but one capacitor of the second plurality of capacitors having their second electrodes selectively connected to the third voltage level, the fourth voltage level, and the fifth voltage level.

11. The apparatus of claim 9, wherein the controller being configured to cause the apparatus to perform the successive approximation with each second electrode of the first plurality of capacitors selectively connected to at least the second voltage level and the fourth voltage level, with each second electrode of the second plurality of capacitors selectively connected to at least the third voltage level and the fourth voltage level, and with one or more second electrodes of the first plurality of capacitors and of the second plurality of capacitors further selectively connected to the fifth voltage level comprises the controller being configured to cause the apparatus to perform the successive approximation with each second electrode of the first plurality of capacitors selectively connected to the second voltage level, the fourth voltage level, and the fifth voltage level, and with each second electrode of the second plurality of capacitors selectively connected to the third voltage level, the fourth voltage level, and the fifth voltage level.

12. The apparatus of claim 9, wherein the controller being configured to cause the apparatus to perform the successive approximation further comprises the controller being configured to:
apply the fourth voltage level to each second electrode of the first plurality of capacitors and to each second electrode of the second plurality of capacitors; and
generate a first digit of an M-digit non-binary output value representative of the difference between the second voltage level and the third voltage level in response to a value at the output of the comparator while electrically floating the first input of the comparator and the second input of the comparator after applying the first voltage level to the first input of the comparator and to the second input of the comparator, and while applying the fourth voltage level to each second electrode of the first plurality of capacitors and to each second electrode of the second plurality of capacitors, wherein the first digit of the M-digit non-binary output value is generated to have a first value in response to the first input of the comparator having a higher voltage level than the second input of the comparator, and wherein the first digit of the M-digit non-binary output value is generated to have a second value, different than the first value, in response to the first input of the comparator having a lower voltage level than the second input of the comparator.

13. The apparatus of claim 12, wherein the controller is further configured to cause the apparatus to apply the fifth voltage level to the second electrode of a first capacitor of the first plurality of capacitors in response to the first digit of the M-digit non-binary output value having the first value, and to apply the fifth voltage level to the second electrode of a first capacitor of the second plurality of capacitors in response to the first digit of the M-digit non-binary output value having the second value.

14. The apparatus of claim 13, wherein the controller is further configured to cause the apparatus to generate a second digit of the M-digit non-binary output value in response to a value at the output of the comparator after applying the fifth voltage level to the second electrode of the first capacitor of either the first plurality of capacitors or the second plurality of capacitors in response to the first digit of the M-digit non-binary output value.

15. An apparatus, comprising:
a fully-differential amplifier (FDA) having a first input, a second input, a first output and a second output; and
a successive approximation register analog-to-digital converter (SAR ADC) comprising:
a comparator having a first input, a second input, and an output;
a first array of capacitors, wherein each capacitor of the first array of capacitors has a first electrode connected to the first input of the comparator, and a second electrode;
a second array of capacitors, wherein each capacitor of the second array of capacitors has a first electrode connected to the second input of the comparator, and a second electrode, and wherein each capacitor of the second array of capacitors corresponds to a respective capacitor of the first array of capacitors; and
a controller configured to cause the apparatus to:
apply a first voltage level to the first input of the FDA, apply a first reference voltage level, independent of the first voltage level, to the second input of the FDA, generate a second voltage level at the first output of the FDA, and generate a third voltage level at the second output of the FDA;
apply a common mode voltage level, between the second voltage level and the third voltage level, to each first electrode of the first plurality of capacitors and to each first electrode of the second plurality of capacitors, then electrically float each first electrode of the first plurality of capacitors and each first electrode of the second plurality of capacitors;
while applying the first voltage level to each first electrode of the first plurality of capacitors and to each first electrode of the second plurality of capacitors, apply the second voltage level to each second electrode of the first plurality of capacitors and apply the third voltage level to each second electrode of the second plurality of capacitors;
apply a second reference voltage level higher than the common mode voltage level to each second electrode of the first plurality of capacitors and to each second electrode of the second plurality of capacitors;
generate a first digit of a non-binary output value having M digits in response to an output value of the comparator, wherein M is equal to a number of capacitors of the first plurality of capacitors, and wherein a number of capacitors of the second plurality of capacitors is equal to a number of capacitors of the first plurality of capacitors;
in response to the first digit of the non-binary output value having a first value indicative of the first input of the comparator receiving a higher voltage level than the second input of the comparator, apply a third reference voltage level lower than the common mode voltage level to the second electrode of a first capacitor of the first plurality of capacitors, and in response to the first digit of the non-binary output value not having the first value, apply the third reference voltage level to the second electrode of a first capacitor of the second plurality of capacitors;
generate a second digit of the non-binary output value in response to the output value of the comparator;
for i=2 to M−1, step 1:
in response to the i^{th} digit of the non-binary output value having the first value, apply the third reference voltage level to the second electrode of an i^{th} capacitor of the first plurality of capacitors, and in response to the i^{th} digit of the non-binary output value not having the first value, apply the third reference voltage level to the second electrode of an i^{th} capacitor of the second plurality of capacitors; and
generate an (i+1)^{th} digit of the non-binary output value in response to the output value of the comparator; and
generate an N-digit binary output vector in response to the M-digit non-binary output value, where N<M.

16. The apparatus of claim 15, wherein a capacitance level of a capacitor of the first plurality of capacitors having a lowest capacitance level of any capacitor of the first plurality of capacitors is equal to C, wherein C is a positive value of Farads, and wherein a sum of capacitance levels for each capacitor of the first plurality of capacitors is equal to 2\hat{ }(N−1)*C.

17. The apparatus of claim 16, wherein a capacitance level of each capacitor of the second plurality of capacitors is equal to the capacitance level of its respective capacitor of the first plurality of capacitors.

18. The apparatus of claim 17, wherein a capacitance level of each capacitor of the first plurality of capacitors, and of each capacitor of the second plurality of capacitors, is a multiple of C.

19. The apparatus of claim 18, wherein the apparatus further comprises:
an array of memory cells comprising a plurality of strings of series-connected memory cells;
a common source selectively connected to each string of series-connected memory cells of the plurality of strings of series-connected memory cells; and
a transimpedance amplifier (TIA) having a first input selectively connected to the common source, a second input configured to receive the first reference voltage level, an output, and an impedance connected between the first input and the output, wherein the first input of the TIA is further selectively directly connected to the output of the TIA bypassing the impedance;
wherein the controller is further configured to cause the apparatus to generate the first voltage level at the output of the TIA in response to a current flow from the array of memory cells to the common source.

20. The apparatus of claim 15, wherein a value of the N-digit binary output vector in base 10 is defined as:
$$2 \hat{} ( N - 1 ) + [ {\sum }_{k = 1}^{M - 1} ( ( 2 * {D}_{k} ) - 1 ) * C ( k ) ] + ( {D}_{M} - 1 )$$
Where:
Dₖ is a k^{th} digit of the M-digit non-binary output value, with k=1 to M; and
C(k) is a relative capacitance level of a k^{th} capacitor of the first plurality of capacitors as a multiple of the value C.
